(19) United States
(12) Patent Application Publication
(10) Pub. No.: US 2026/0371618 A1
(43) Pub. Date: Nov. 19, 2026

(54) SEMICONDUCTOR DEVICES INCLUDING HYDROGEN DIFFUSION PATH

(71) Applicant: SAMSUNG ELECTRONICS CO., LTD., Suwon-si (KR)

(72) Inventors: Heonjun HA, Suwon-si (KR); Chaebeen KWON, Suwon-si (KR); Jihee JUN, Suwon-si (KR); Hana CHO, Suwon-si (KR); Chanhee HAN, Suwon-si (KR)

(73) Assignee: SAMSUNG ELECTRONICS CO., LTD., Suwon-si (KR)

(21) Appl. No.: 19/681,988

(22) Filed: May 19, 2026

(30) Foreign Application Priority Data
May 19, 2025 (KR) 10-2025-0064784

(51) Int. Cl. H10B 80/00; H10W 80/00; H10W 90/00; H10W 90/20; H10W 90/26

(52) U.S. Cl. CPC H10B 80/00; H10W 80/312; H10W 90/26; H10W 90/297; H10W 90/792

(57) ABSTRACT

A semiconductor device includes a transistor layer, a wiring layer, a bonding layer, a memory cell layer and a hydrogen diffusion path. The transistor layer includes a transistor on a first region of a substrate. The wiring layer is on the transistor layer, and includes a first wiring structure on the first region. The bonding layer is on the wiring layer, and includes a first bonding pad structure on the first region. The memory cell layer is disposed on the bonding layer. The hydrogen diffusion path is spaced apart from the transistor and extends through the memory cell layer, the bonding layer and the wiring layer on a second region of the substrate, and contacts an upper surface of the substrate. The memory cell layer includes a bit line structure, a channel, a gate structure, and a capacitor structure.

### CROSS-REFERENCE TO RELATED APPLICATION

This application claims priority under 35 U.S.C. § 119 to Korean Patent Application No. 10-2025-0064784 filed on May 19, 2025 in the Korean Intellectual Property Office, the disclosure of which is hereby incorporated by reference in its entirety.

### TECHNICAL FIELD

Example embodiments of the present disclosure relate to a semiconductor device.

### DISCUSSION OF RELATED ART

A semiconductor device may be manufactured by forming a memory cell and a periphery circuit pattern on separate substrates, and bonding the substrates to each other. In such a structure, the memory cell and the periphery circuit pattern may be located on different planes. As a result, the length and complexity of a hydrogen passivation path may increase, and non-uniformity in the degree of hydrogen passivation may occur among regions.

### SUMMARY

Example embodiments provide a semiconductor device having improved characteristics.

According to example embodiments, there is provided a semiconductor device. The semiconductor device may include a transistor layer, a wiring layer, a bonding layer, a memory cell layer and a hydrogen diffusion path. The transistor layer may include a transistor on a first region of a substrate, and the substrate may include the first region and a second region. The wiring layer may be disposed on the transistor layer, and may include a first wiring structure on the first region of the substrate. The bonding layer may be disposed on the wiring layer, and may include a first bonding pad structure on the first region of the substrate. The memory cell layer may be disposed on the bonding layer. The hydrogen diffusion path may be spaced apart from the transistor and may extend through the memory cell layer, the bonding layer and the wiring layer on the second region of the substrate, and may contact an upper surface of the substrate. The memory cell layer may include a bit line structure, a channel on the bit line structure, a gate structure at a side of the channel on the bit line structure, and a capacitor structure on the channel.

According to example embodiments, there is provided a semiconductor device. The semiconductor device may include a memory cell layer, a bonding layer, a wiring layer, a second substrate, a transistor layer, and a hydrogen diffusion path. The memory cell layer may include a capacitor structure on a first region of a first substrate including the first region and a second region, a channel on the capacitor structure, a gate structure at a side of the channel on the capacitor structure, a bit line structure on the channel, and a first contact plug structure overlapping the capacitor structure, the channel and the bit line structure in a horizontal direction parallel to an upper surface of the first substrate. The bonding layer may be disposed on the memory cell layer, and may include a first bonding pad structure on the first region of the first substrate. The wiring layer may be disposed on the bonding layer, and may include a first wiring structure on the first region of the first substrate. The second substrate may be disposed on the wiring layer, and may include a first main surface and a second main surface opposite to each other. The transistor layer may include a transistor and a first through via structure. The transistor may be disposed on the first main surface of the second substrate on the first region of the first substrate, and the first through via structure may extend through the first and second main surfaces of the second substrate on the first region of the first substrate. The hydrogen diffusion path may be spaced apart from the transistor and may include a second contact plug structure, a second bonding pad structure, a second wiring structure and a second through via structure sequentially stacked on an upper surface of the second region of the first substrate in a vertical direction perpendicular to the upper surface of the first substrate. The second contact plug structure may at least partially extend through the memory cell layer, the second bonding pad structure may extend through the bonding layer, the second wiring structure may extend through the wiring layer, and the second through via structure may extend through the first and second main surfaces of the second substrate.

According to example embodiments, there is provided a semiconductor device. The semiconductor device may include a memory cell layer, a second substrate, a transistor layer, and hydrogen diffusion path. The memory cell layer may include a capacitor structure on a first region of a first substrate including the first region and a second region, a channel on the capacitor structure, a gate structure at a side of the channel on the capacitor structure, a bit line structure on the channel, and a first contact plug structure overlapping the capacitor structure, the channel and the bit line structure in a horizontal direction parallel to an upper surface of the first substrate. The second substrate may be disposed on the memory cell layer. The transistor layer may include a transistor and a first through via structure, and may be disposed on an upper surface of the second substrate on the first region of the first substrate. The first through via structure may extend through the second substrate on the first region of the first substrate. The hydrogen diffusion path may be spaced apart from the transistor and may include a second contact plug structure and a second through via structure sequentially stacked on an upper surface of the second region of the first substrate in a vertical direction perpendicular to the upper surface of the first substrate. The second contact plug structure may at least partially extend through the memory cell layer, and may be disposed at the same vertical level as the first contact plug structure. The second through via structure may extend through the second substrate, and may be disposed at the same vertical level as the first through via structure.

In the semiconductor device in accordance with example embodiments, the hydrogen diffusion path may be formed on a region of the substrate in which the transistor of the peripheral circuit pattern is not disposed, so that hydrogen passivation efficiency may be improved. The hydrogen diffusion path may include first conductive patterns, which may be distinguished from second conductive patterns for electrically connecting the memory cell and the peripheral circuit pattern. Thus, hydrogen may rapidly diffuse to the upper surface of the substrate through the first conductive patterns sequentially stacked in the vertical direction instead of the second conductive patterns that may be arranged in a complex structure for electrically connecting the memory cell and the peripheral circuit pattern. Accordingly, the efficiency and uniformity of the hydrogen passivation may be enhanced, and the semiconductor device may have improved reliability.

### BRIEF DESCRIPTION OF THE DRAWINGS

FIG. 1 is a cross-sectional view illustrating a semiconductor device in accordance with example embodiments.

FIG. 2 is a cross-sectional view illustrating a semiconductor device in accordance with example embodiments.

FIG. 3 is a cross-sectional view illustrating a semiconductor device in accordance with example embodiments.

FIG. 4 is a cross-sectional view illustrating a semiconductor device in accordance with example embodiments.

FIG. 5 is a cross-sectional view illustrating a semiconductor device in accordance with example embodiments.

FIG. 6 is a cross-sectional view illustrating a semiconductor device in accordance with example embodiments.

FIGS. 7, 8, 9, 10, 11, 12, 13, 14, and 15 are plan views and cross-sectional views illustrating a method of manufacturing a semiconductor device in accordance with example embodiments.

FIGS. 16, 17, 18, 19, and 20 are cross-sectional views illustrating a method of manufacturing a semiconductor device in accordance with example embodiments.

### DETAILED DESCRIPTION

The above and other aspects and features of a semiconductor device and a method of manufacturing the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, in the specification (and not necessarily in the claims), two directions that are substantially perpendicular to each other among horizontal directions, which are substantially parallel to an upper surface of each of first, second and third substrates, may be referred to as first and second directions D1 and D2, respectively, and a vertical direction substantially perpendicular to the upper surface of each of the first to third substrates may be referred to as a third direction D3. In example embodiments, the first and second directions D1 and D2 may be orthogonal to each other. Each of the first to third directions D1, D2 and D3 may include not only a direction shown in the drawings but also a direction that is inverse thereto.

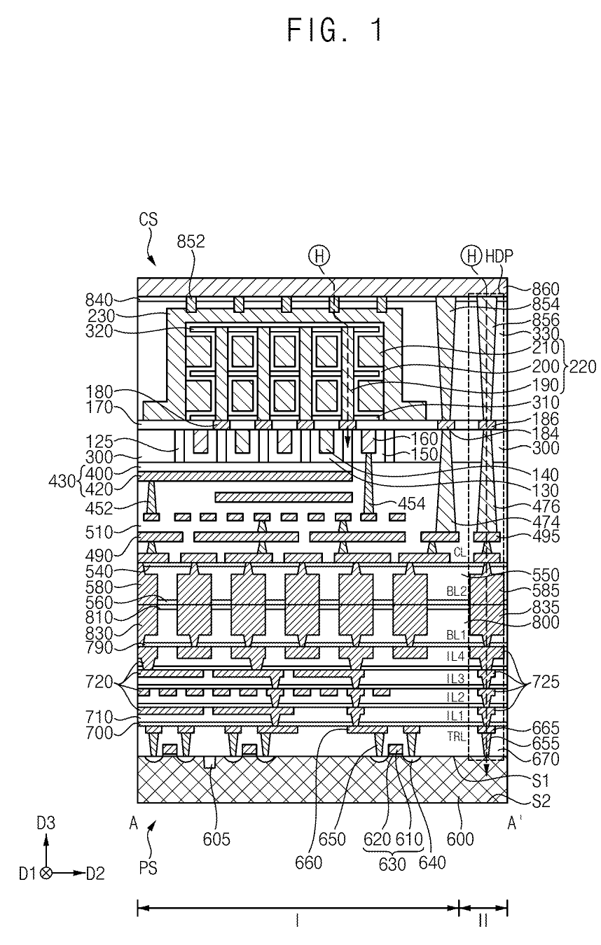

FIG. 1 is a cross-sectional view illustrating a semiconductor device in accordance with example embodiments.

Referring to FIG. 1, the semiconductor device may include a periphery circuit structure PS, a cell structure CS including memory cells, and a hydrogen diffusion path HDP on a third substrate 600.

The semiconductor device may have a cell over periphery (COP) structure in which the cell structure CS is disposed on the periphery circuit structure PS.

The periphery circuit structure PS may include a transistor layer TRL, a plurality of wiring layers IL1, IL2, … ILn, and a first bonding layer BL1 sequentially stacked on the third substrate 600 in the third direction D3.

The third substrate 600 may include a first region I and a second region II. The first region I of the third substrate 600 may be a cell region on which memory cells and transistors (e.g., cell transistors) are disposed. The second region II of the third substrate 600 may be a region on which the memory cells or the transistors are not disposed. The second region II of the third substrate 600 may surround the first region I of the third substrate 600, or may be disposed at one side or both sides in the horizontal direction, however, the inventive concept is not limited thereto.

The third substrate 600 may include a semiconductor material, e.g., silicon, germanium, silicon-germanium, etc. The third substrate 600 may include first and second main surfaces S1 and S2 opposite to each other in the third direction D3.

An isolation pattern 605 may be disposed on the first main surface S1 of the third substrate 600. The isolation pattern 605 may include an oxide, e.g., silicon oxide.

The transistor layer TRL may include transistors, seventh conductive patterns (e.g., first contact plugs 650, first wirings 660, etc.), and a first insulating interlayer 670 covering the seventh conductive patterns.

The transistors may be disposed on the first region I of the third substrate 600, and may be disposed on the first main surface S1 of the third substrate 600, that is, on an upper surface of the third substrate 600. Each of the transistors may include, e.g., a third gate structure 630 on the first main surface S1 of the third substrate 600, and impurity regions 640 at portions of the third substrate 600 adjacent to the third gate structure 630. In example embodiments, the transistors may be spaced apart from each other in the horizontal direction on the first region I of the third substrate 600.

The third gate structure 630 may include a third gate insulation pattern 620 and a third gate electrode 610 stacked in the third direction D3 on the first main surface S1 of the third substrate 600. The third gate electrode 610 may include a conductive material, e.g., a metal, a metal nitride, a metal silicide, doped polysilicon, etc. The third gate insulation pattern 620 may include an oxide, e.g., silicon oxide.

The first contact plugs 650 may contact upper surfaces of the impurity regions 640, respectively. The first wirings 660 may contact upper surfaces of the first contact plugs 650, respectively. FIG. 1 shows that the seventh conductive patterns include the first contact plugs 650 and the first wirings 660, however, the inventive concept is not limited thereto. For example, the seventh conductive patterns may include additional contact plugs and/or additional wirings in the transistor layer TRL.

The first insulating interlayer 670 may cover the transistors and the seventh conductive patterns on the third substrate 600.

The wiring layers IL1, IL2, … , ILn may be sequentially stacked on the transistor layer TRL in the third direction D3. That is, the wiring layers IL1, IL2, … , ILn may be sequentially stacked on the first main surface S1 of the third substrate 600. FIG. 1 shows only four wiring layers IL1, IL2, IL3 and IL4, however, the inventive concept is not limited thereto, and the semiconductor device may include a greater or a smaller number of wiring layers. Hereinafter, for convenience of explanation, an arbitrary wiring layer Ili among the wiring layers IL1, IL2, … , ILn is described.

The wiring layer ILimay include a first etch stop layer 700, a second insulating interlayer 710 and first wiring structures 720.

The first etch stop layer 700 may cover an upper surface of the transistor layer TRL or an upper surface of a lower one IL(i-1) of the wiring layers IL1, IL2, … , ILn.

The first wiring structures 720 of the wiring layer ILi may extend through the second insulating interlayer 710 and the first etch stop layer 700 of the wiring layer ILi and may contact the seventh conductive patterns of the transistor layer TRL, or the first wiring structures 720 of the lower one IL(i-1) of the wiring layers IL1, IL2, … , ILn. Likewise, the first wiring structures 720 of each wiring layer of the wiring layers IL1, IL2, … , ILn may extend through the insulating interlayer 710 to contact conductive patterns of the lower one IL(i-1) of the wiring layers IL1, IL2, … , ILn, so that an electrical connection between the wiring layers IL1, IL2, … , ILn may be formed.

In example embodiments, the first wiring structure 720 may include a plug portion and a wiring portion disposed on and connected to the plug portion. In example embodiments, the plug portion of the first wiring structure 720 may extend through the first etch stop layer 700 and a lower portion of the second insulating interlayer 710, and the wiring portion of the first wiring structure 720 may extend through an upper portion of the second insulating interlayer 710. In example embodiments, the wiring portion may have a shape of a line. In example embodiments, a sidewall of the wiring portion may be surrounded by the second insulating interlayer 710, and a lower surface of the wiring portion may be disposed in the second insulating interlayer 710.

The first etch stop layer 700 may include, e.g., silicon nitride, silicon carbonitride, silicon carbide, etc. The second insulating interlayer 710 may include an oxide, e.g., silicon oxide. The first wiring structure 720 may include a metal, e.g., copper, tungsten, etc., or a metal nitride, e.g., titanium nitride, tungsten nitride, etc.

The first bonding layer BL1 may be disposed on an uppermost one ILn of the wiring layers IL1, IL2, … , ILn. The first bonding layer BL1 may include a second etch stop layer 790, a third insulating interlayer 800, a first adhesion layer 810 and first bonding pad 830.

The second etch stop layer 790 may cover an upper surface of the uppermost one ILn of the wiring layers IL1, IL2, … , ILn. The third insulating interlayer 800 may be disposed on the second etch stop layer 790. The first adhesion layer 810 may cover an upper surface of the third insulating interlayer 800.

In example embodiments, a plurality of first bonding pads 830 may be spaced apart from each other in the horizontal direction on the first region I of the third substrate 600. The first bonding pad 830 may extend through the first adhesion layer 810, the third insulating interlayer 800 and the second etch stop layer 790 and may contact an upper surface of the first wiring structure 720 of the uppermost one ILn of the wiring layers IL1, IL2, … , ILn. In example embodiments, the first bonding pad 830 may include a lower portion, and an upper portion disposed on the lower portion and having a width greater than that of the lower portion.

The second etch stop layer 790 may include, e.g., silicon nitride, silicon carbonitride, silicon carbide, etc. The third insulating interlayer 800 may include an oxide, e.g., silicon oxide. The first adhesion layer 810 may include, e.g., silicon carbide. The first bonding pad 830 may include, e.g., copper.

The cell structure CS may include a second bonding layer BL2 and a memory cell layer CL sequentially stacked on the periphery circuit structure PS.

The second bonding layer BL2 may be disposed on the first bonding layer BL1. The second bonding layer BL2 may include a third etch stop layer 540, a fourth insulating interlayer 550, a second adhesion layer 560 and a third bonding pad 580.

The third etch layer 540 may cover a lower surface of the memory cell layer CL. The fourth insulating interlayer 550 may be disposed under the third etch stop layer 540. The second adhesion layer 560 may cover a lower surface of the fourth insulating interlayer 550. A lower surface of the second adhesion layer 560 may contact an upper surface of the first adhesion layer 810, and may bond the periphery circuit structure PS and the cell structure CS to each other.

In example embodiments, a plurality of third bonding pads 580 may be spaced apart from each other in the horizontal direction on the first region I of the third substrate 600. The third bonding pad 580 may extend through the third etch stop layer 540, the fourth insulating interlayer 550 and the second adhesion layer 560 and may contact an upper surface of the first bonding pad 830. Thus, the periphery circuit structure PS and the cell structure CS may be electrically connected to each other through the first and third bonding pads 830 and 580. In example embodiments, the third bonding pad 580 may include a lower portion, and an upper portion disposed on the lower portion and having a width less than that of the lower portion.

The first and third bonding pads 830 and 580 may collectively form a first bonding pad structure.

The third etch stop layer 540 may include, e.g., silicon nitride, silicon carbonitride, silicon carbide, etc. The fourth insulating interlayer 550 may include an oxide, e.g., silicon oxide. The second adhesion layer 560 may include, e.g., silicon carbide. The third bonding pad 580 may include, e.g., copper.

The memory cell layer CL may include a bit line 430, first and second gate structures, a channel 125, a capacitor structure 220, a plate electrode 230, first and second conductive pads 180 and 184, third to fifth contact plugs 452, 454 and 474, a fifth conductive pattern 490, seventh and eighth contact plugs 852 and 854, and a third wiring 860. The memory cell layer CL may further include fifth to eighth insulating interlayers 510, 300, 170 and 330 and a fifth etch stop layer 840.

The semiconductor device may have a back-to-back structure in which a distance between the bit line structure 430 and the first main surface S1 of the third substrate 600 is less than a distance between the capacitor structure 220 and the first main surface S1 of the third substrate 600.

The bit line structure 430 may be disposed on the second bonding layer BL2 on the first region I of the third substrate 600. The bit line structure 430 may extend in the second direction D2, and a plurality of bit line structures 430 may be spaced apart from each other in the first direction D1.

In example embodiments, the bit line structure 430 may include third and fourth conductive patterns 400 and 420 stacked in the third direction D3, and may include, e.g., doped polysilicon or a metal.

The first and second gate structures and the channel 125 may be disposed on the bit line structure 430, and may extend through the sixth insulating interlayer 300 on the fifth insulating interlayer 510.

The first gate structure may include a first gate electrode 140 and a first gate insulation pattern 130. The second gate structure may include a second gate electrode 160 and a second gate insulation pattern 150.

In example embodiments, the first gate electrode 140 may extend in the first direction D1, and a plurality of first gate electrodes 140 may be spaced apart from each other in the second direction D2. The second gate electrode 160 may extend in the first direction D1 at the same vertical level as the first gate electrode 140, and a plurality of second gate electrodes 160 may be spaced apart from each other in the second direction D2. In example embodiments, the first and second gate electrodes 140 and 160 may be alternately and repeatedly disposed in the second direction D2.

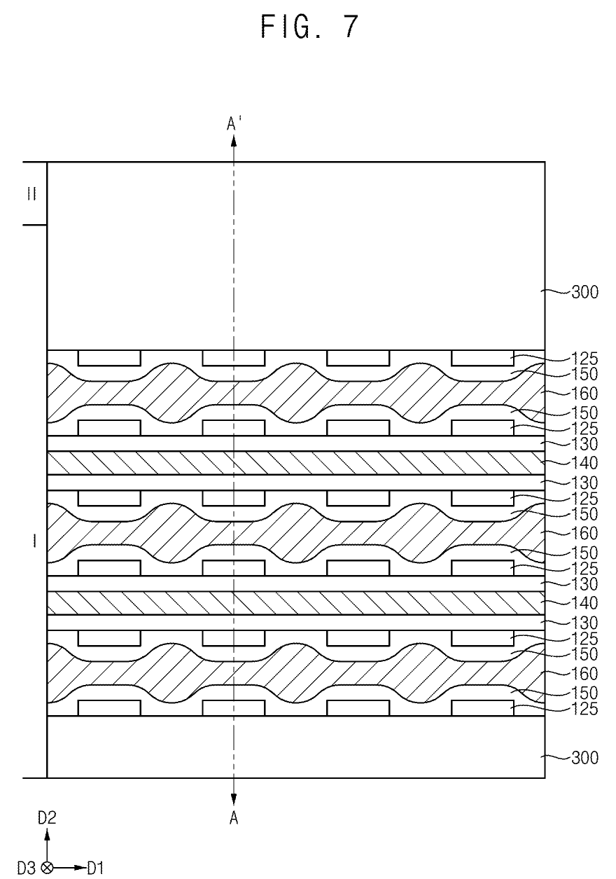

Referring to FIG. 1 together with FIG. 7, the first gate electrode 140 may have a shape of a straight line extending in the first direction D1 in a plan view, and the second gate electrode 160 may have a shape of a straight line extending in the first direction D1 and including protrusion portions protruding in the second direction D2 and being spaced apart from each other in the first direction D1 in a plan view.

Each of the first and second gate electrodes 140 and 160 may include a metal, e.g., tungsten, copper, aluminum, etc.

In example embodiments, the second gate electrode 160 may serve as a word line of the semiconductor device, and the first gate electrode 140 may serve as a back gate of the semiconductor device. However, the inventive concept is not limited thereto, and in some cases, the first and second gate electrodes 140 and 160 may serve as the word line and the back gate, respectively.

In example embodiments, the first gate insulation pattern 130 may be disposed on the fifth insulating interlayer 510 and the bit line structure 430, and may extend in the first direction D1 and cover a lower surface and a sidewall of the first gate electrode 140. The second gate insulation pattern 150 may be disposed on the fifth insulating interlayer 510 and the bit line structure 430, and may extend in the first direction D1 and cover a lower surface and a sidewall of the second gate electrode 160. In example embodiments, a vertical cross-section in the second direction D2 of each of the first and second gate insulation patterns 130 and 150 may have a shape of, e.g., a cup.

As the first and second gate electrodes 140 and 160 are alternately and repeatedly disposed in the second direction D2, the first and second gate insulation patterns 130 and 150 may be alternately and repeatedly disposed in the second direction D2.

In example embodiments, each of opposite sidewalls in the second direction D2 of the first gate insulation pattern 130 may have a shape of a straight line extending in the first direction D1 in a plan view, while each of opposite sidewalls in the second direction D2 of the second gate insulation pattern 150 may have a shape of zigzag in a plan view. Each of the first and second gate insulation patterns 130 and 150 may include an oxide, e.g., silicon oxide.

In example embodiments, a plurality of channels 125 may be spaced apart from each other in the second direction D2 on the bit line structure 430 extending in the second direction D2. Each of the channels 125 may be disposed between ones of the first and second gate electrodes 140 and 160 neighboring in the second direction D2. Thus, the first and second gate structures may be disposed at respective opposite sides of the channel 125.

A first sidewall in the second direction D2 of the channel 125 may contact an outer sidewall in the second direction D2 of the first gate insulation pattern 130, and a second sidewall in the second direction D2 of the channel 125 and opposite sidewalls in the first direction D1 of the channel 125 may contact an outer sidewall in the second direction D2 of the second gate insulation pattern 150.

In example embodiments, the channel 125 may include a semiconductor material, e.g., silicon, germanium, silicon-germanium, etc. Alternatively, the channel 125 may include an oxide semiconductor material, e.g., Indium Gallium Zinc Oxide (IGZO).

The first conductive pad 180 may be disposed between the channel 125 and the capacitor structure 220. In example embodiments, the first conductive pad 180 may extend through the seventh insulating interlayer 170 on the sixth insulating interlayer 300. In example embodiments, a plurality of first conductive pads 180 may be spaced apart from each other in each of the first and second directions D1 and D2.

The second conductive pad 184 may be disposed at substantially the same vertical level as the first conductive pad 180. In example embodiments, the second conductive pad 184 may extend through the seventh insulating interlayer 170 on the sixth insulating interlayer 300.

In example embodiments, each of the first and second conductive pads 180 and 184 may include first and second conductive patterns sequentially stacked in the third direction D3. The first conductive pattern may include, e.g., doped polysilicon. The second conductive pattern may include, e.g., a metal, a metal nitride, a metal silicide, etc.

The fifth conductive pattern 490 may include wirings, vias or contact plugs between the second bonding layer BL2 and the bit line structure 430.

The third contact plug 452 may contact a lower surface of the bit line structure 430. The bit line structure 430 may be electrically connected to the peripheral circuit structure PS through the third contact plug 452, the fifth conductive pattern 490 and the first bonding pad structure.

The fourth contact plug 454 may contact a lower surface of the second gate electrode 160 included in the second gate structure or the first gate electrode 140 included in the first gate structure. The first and second gate structures may be electrically connected to the peripheral circuit structure PS through the fourth contact plug 454, the fifth conductive pattern 490 and the first bonding pad structure.

The fifth contact plug 474 may contact a lower surface of the second conductive pad 184.

The fifth insulating interlayer 510 may cover the fifth conductive pattern 490 and the third to fifth contact plugs 452, 454 and 474.

In example embodiments, each of the third to fifth contact plugs 452, 454 and 474 may have a width gradually decreasing from a bottom toward a top thereof.

The capacitor structure 220 may include a first capacitor electrode 190, a second capacitor electrode 210 and a dielectric layer 200 therebetween. The first capacitor electrode 190 may contact an upper surface of the first conductive pad 180 and may extend in the third direction D3. In example embodiments, a plurality of first capacitor electrodes 190 may be spaced apart from each other in each of the first and second directions D1 and D2, and may be arranged in a lattice pattern or a honeycomb pattern in a plan view.

A support layer 320 and a fourth etch stop layer 310 may be disposed on a sidewall of the first capacitor electrode 190. The fourth etch stop layer 310 may be disposed on a lowermost portion of the sidewall of the first capacitor electrode 190, and a plurality of support layers 320 may be spaced apart from each other in the sidewall of the first capacitor electrode 190.

The dielectric layer 200 may cover a sidewall of the first capacitor electrode 190, lower and upper surfaces and a sidewall of the support layer 320, and an upper surface and a sidewall of the fourth etch stop layer 310. The second capacitor electrode 210 may be disposed between the support layers 320 and between the fourth etch stop layer 310 and a lowermost one of the support layers 320, and lower and upper surfaces and a sidewall of the second capacitor electrode 210 may be covered by the dielectric layer 200.

The plate electrode 230 may be disposed on the seventh insulating interlayer 170, and may cover an upper surface and a sidewall of the capacitor structure 220.

Each of the first and second capacitor electrodes 190 and 210 may include a conductive material, e.g., a metal, a metal nitride, a metal silicide, etc. The dielectric layer 200 may include a high-k dielectric material, e.g., a metal oxide. The support layer 320 may include an insulating nitride, e.g., silicon nitride. The fourth etch stop layer 310 may include an insulating nitride, e.g., silicon boronitride. The plate electrode 230 may include, e.g., doped silicon-germanium or a metal such as tungsten.

The eighth insulating interlayer 330 may be disposed on the seventh insulating interlayer 170, and may cover the capacitor structure 220 and the plate electrode 230. The fifth etch stop layer 840 may be disposed on the eighth insulating interlayer 330.

The seventh contact plug 852 may extend through the fifth etch stop layer 840 and an upper portion of the eighth insulating interlayer 330, and may contact an upper surface of the plate electrode 230. In example embodiments, a plurality of seventh contact plugs 852 may be spaced apart from each other in the horizontal direction.

The eighth contact plug 854 may extend through the fifth etch stop layer 840 and the eighth insulating interlayer 330, and may contact an upper surface of the second conductive pad 184. In example embodiments, a plurality of eighth contact plus 854 may be spaced apart from each other in the first direction D1. The eighth contact plug 854 may have a width gradually increasing from a bottom toward a top thereof.

The eighth contact plug 854, the second conductive pad 184 and the fifth contact plug 474 may collectively form a first contact plug structure. The first contact plug structure may at least partially extend through the memory cell layer CL. In example embodiments, a plurality of first contact plug structures may be spaced apart from each other in the first direction D1.

The third wiring 860 may be disposed on the fifth etch stop layer 840, and may contact an upper surface of the seventh contact plug 852 or the eighth contact plug 854.

The capacitor structure 220 may be electrically connected to the peripheral circuit structure PS through the plate electrode 230, the seventh contact plug 852, the third wiring 860, the first contact plug structure, the fifth conductive pattern 490 and the first bonding pad structure.

Each of the first and third wirings 660 and 860, each of the first, third, fourth, fifth, seventh and eighth contact plugs 650, 452, 454, 474, 852 and 854, and the fifth contact pattern 490 may include a conductive material, e.g., a metal, a metal nitride, a metal silicide, etc. Each of the fifth to eight insulating interlayers 510, 300, 170 and 330 may include an oxide, e.g., silicon oxide, and some of the fifth to eight insulating interlayers 510, 300, 170 and 330 may be merged with each other.

The hydrogen diffusion path HDP may be formed on the second region II of the third substrate 600. The hydrogen diffusion path HDP may extend in the third direction D3 through the memory cell layer CL, the first and second bonding layers BL1 and BL2, the wiring layers IL1, IL2, …, ILn, and the transistor layer TRL, and may contact an upper surface of the third substrate 600. In example embodiments, the hydrogen diffusion path HDP may extend through the fifth etch stop layer 840, the fifth to eighth insulating interlayers 510, 300, 170 and 330, the third etch stop layer 540, the fourth insulating interlayer 550, the first and second adhesion layers 810 and 560, the third insulating interlayer 800, the second etch stop layer 790, the second insulating interlayers 710, the first etch stop layers 700 and the first insulating interlayer 670, and may contact the upper surface of the third substrate 600.

The hydrogen diffusion path HDP may include a plurality of conductive patterns that are sequentially stacked in the third direction D3. The conductive patterns of the hydrogen diffusion path HDP may be disposed at the same vertical levels corresponding to those of conductive patterns on the first region I of the third substrate 600. As described below, the conductive patterns of the hydrogen diffusion path HDP may be formed by the same processes for forming the conductive patterns on the first region I of the third substrate 600. Thus, the hydrogen diffusion path HDP may be formed with no additional processes.

The expression “disposed at the same vertical level” means, for example, that a first element and a second element are present at the same height when measured in a vertical direction with respect to a main surface of a substrate. More specifically, the first element and the second element may be arranged within the same layer. Such an arrangement suggests that the firs element and the second element may be formed through a single process, and accordingly may be provided within the same material layer.

The conductive patterns may include various elements for transmitting electrical signals, e.g., wirings, vias, contact plugs, bonding pads, etc.

In example embodiments, the hydrogen diffusion path HDP may include eighth conductive patterns (e.g., a second contact plug 655, a second wiring 665, etc.), a second wiring structure 725, second and fourth bonding pads 835 and 585, a sixth conductive pattern 495, a sixth contact plug 476, a third conductive pad 186 and a ninth contact plug 856.

In example embodiments, the eighth conductive patterns may be disposed in the transistor layer TRL. In example embodiments, the eighth conductive patterns (e.g., the second contact plug 655, the second wiring 665, etc.) may be disposed at the same vertical levels, respectively, as the seventh conductive patterns (e.g., the first contact plug 650, the first wiring 660, etc.). In example embodiments, the eighth conductive patterns may include substantially the same materials as corresponding ones of the seventh conductive patterns.

In example embodiments, a plurality of second wiring structures 725 may be disposed at the wiring layers IL1, IL2, … , ILn, respectively. In example embodiments, the second wiring structures 725 may be disposed at the same vertical levels, respectively, as the first wiring structures 720. In example embodiments, the second wiring structures 725 may include substantially the same materials as corresponding ones of the first wiring structures 720.

In example embodiments, the second and fourth bonding pads 835 and 585 may be disposed in and extend through the first and second bonding layers BL1 and BL2, respectively. The second and fourth bonding pads 835 and 585 may collectively form a second bonding pad structure. In example embodiments, the second bonding pad structure may be disposed at the same vertical level as the first bonding pad structure. In example embodiments, the second and fourth bonding pads 835 and 585 may include substantially the same materials as those of the first and third bonding pads 830 and 580, respectively.

In example embodiments, the sixth conductive pattern 495 may be disposed in the fifth insulating interlayer 510 of the memory cell layer CL. In example embodiments, the sixth conductive pattern 495 may be disposed at the same vertical level as the fifth conductive pattern 490. In example embodiments, the sixth conductive pattern 495 may include substantially the same material as that of the fifth conductive pattern 490.

In example embodiments, the third conductive pad 186 may extend through the seventh insulating interlayer 170, the sixth contact plug 476 may extend through the fifth and sixth insulating interlayers 510 and 300 to contact a lower surface of the third conductive pad 186, and the ninth contact plug 856 may extend through the fifth etch stop layer 840 and the eighth insulating interlayer 330 to contact an upper surface of the third conductive pad 186. The sixth contact plug 476, the third conductive pad 186 and the ninth contact plug 856 may collectively form a second contact plug structure. The second contact plug structure may at least partially extend through the memory cell layer CL.

In example embodiments, the second contact plug structure may be disposed at the same vertical level as the first contact plug structure.

In example embodiments, the sixth contact plug 476 may include substantially the same material as the fifth contact plug 474, the third conductive pad 186 may include substantially the same material as the first and second conductive pads 184 and 186, and the ninth contact plug 856 may include substantially the same material as the eighth contact plug 854.

In example embodiments, the sixth contact plug 476 may have a width gradually decreasing from a bottom toward a top thereof in the third direction D3, and the ninth contact plug 856 may have a width gradually increasing from a bottom toward a top thereof in the third direction D3.

In the semiconductor device, current may flow in the channel 125 disposed between the bit line structure 430 and the first conductive pad 180 in the third direction D3, that is, in the vertical direction, and thus the semiconductor device may be a vertical channel transistor (VCT) DRAM device.

The semiconductor device may be manufactured by forming the cell structure CS and the peripheral circuit structure PS, and bonding the cell structure CS and the peripheral circuit structure PS to each other. The memory cells of the cell structure CS and the peripheral circuit pattern of the peripheral circuit structure PS may be disposed in different planes. Thus, the length and complexity of a hydrogen passivation path may increase, and non-uniformity in the degree of hydrogen passivation may occur among different regions.

To address these issues, the semiconductor device may improve hydrogen passivation efficiency by additionally forming a hydrogen diffusion path HDP on the second region II of the third substrate 600 in which the transistors of the peripheral circuit pattern are not arranged. The hydrogen diffusion path HDP may include separate conductive patterns that are distinguished from existing conductive patterns that electrically connect the cell structure CS and the peripheral circuit structure PS.

According to this structure, hydrogen may rapidly diffusion to the upper surface of the third substrate 600 through conductive patterns sequentially stacked in the third direction D3 on the second region II of the third substrate 600 without passing through the complexly intertwined conductive patterns disposed on the first region I of the third substrate 600. Accordingly, in the semiconductor device, the efficiency and uniformity of hydrogen passivation may be enhanced, thereby improving the reliability of the semiconductor device.

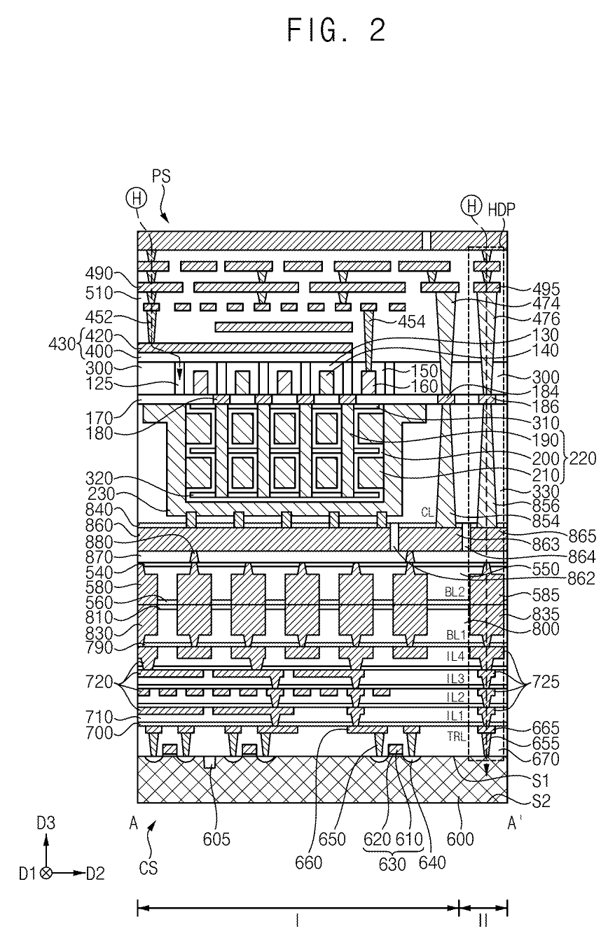

FIG. 2 is a cross-sectional view illustrating a semiconductor device in accordance with example embodiments, which may correspond to FIG. 1. This semiconductor device may be substantially the same as or similar to that of FIG. 1, except for some elements, and thus repeated explanations are omitted herein.

Referring to FIG. 2, the memory cell CL may be vertically inverted compared to that of the semiconductor device shown in FIG. 1.

That is, the semiconductor device may have a face-to-face structure in which a distance between the capacitor structure 220 and the first main surface S1 of the third substrate 600 is less than a distance between the bit line structure 430 and the first main surface S1 of the third substrate 600.

The memory cell layer CL may further include a fourth wiring 863, a first division pattern 862, a ninth conductive pattern 880 and a ninth insulating interlayer 870.

The fourth wiring 863 may be disposed at the same vertical level as the third wiring 860 on the first region I of the third substrate 600. In example embodiments, the fourth wiring 863 may include substantially the same material as the third wiring 860.

In example embodiments, the fourth wiring 863 may be spaced apart from each other in the third wiring 860 by the first division pattern 862. The first division pattern 862 may include an oxide, e.g., silicon oxide.

The ninth insulating interlayer 870 may be disposed under the third and fourth wirings 860 and 863.

The ninth conductive pattern 880 may extend through the ninth insulating interlayer 870 and may contact a lower surface of the third wiring 860 or the fourth wiring 863 and an upper surface of the first bonding pad structure.

The capacitor structure 220 may be electrically connected to the peripheral circuit structure PS through the seventh contact plug 852, the ninth conductive pattern 880 and the first bonding pad structure.

The bit line structure 430 may be electrically connected to the peripheral circuit structure PS through the third contact plug 452, the fifth conductive pattern 490, the first contact plug structure, the fourth wiring 853, the ninth conductive pattern 880 and the first bonding pad structure.

The first and second gate structures may be electrically connected to the peripheral circuit structure PS through the fourth contact plug 454, the fifth conductive pattern 490, the first contact plug structure, the fourth wiring 853, the ninth conductive pattern 880 and the first bonding pad structure.

The hydrogen diffusion path HDP may include the seventh conductive pattern, the second wiring structure 725, the second bonding pad structure, a tenth conductive pattern 885, a fifth wiring 865, the sixth conductive pattern 495, the second contact plug structure and a sixth conductive pattern 495.

The tenth conductive pattern 885 may be disposed at the same vertical level as the ninth conductive pattern 880 on the second region II of the third substrate 600. The tenth conductive pattern 885 may extend through the ninth insulating interlayer 870 and may contact a lower surface of the fifth wiring 865 and an upper surface of the second bonding pad structure. In example embodiments, the tenth conductive pattern 885 may include substantially the same material as the ninth conductive pattern 880.

The fifth wiring 865 may be spaced apart from the fourth wiring 863 by a second division pattern 864. The second division pattern 864 may include an oxide, e.g., silicon oxide.

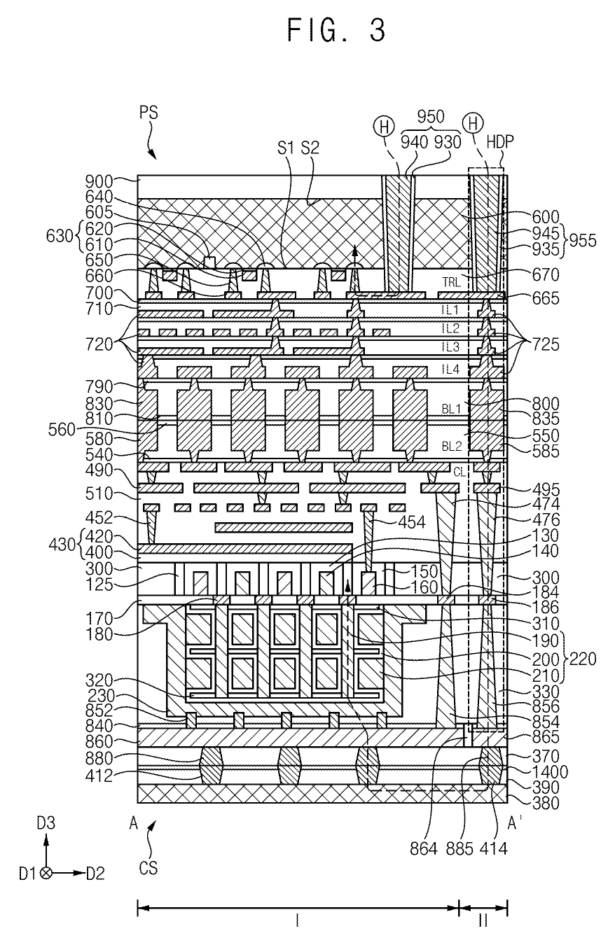

FIG. 3 is a cross-sectional view illustrating a semiconductor device in accordance with example embodiments, which may correspond to FIG. 1. This semiconductor device may be substantially the same as or similar to that of FIG. 1, except for some elements, and thus repeated explanations are omitted herein.

Referring to FIG. 3, the semiconductor device may have a periphery over cell (POC) structure in which the peripheral circuit structure PS is disposed over the cell structure CS. The semiconductor device may be vertically inverted compared to the semiconductor device shown in FIG. 1, and following description is provided on the inverted direction.

The first main surface S1 among the first and second main surfaces S1 and S2 of the third substrate 600 may be adjacent to the memory cell layer CL.

The cell structure CS may further include a second substrate 380, a tenth insulating interlayer 390, a third adhesion layer 1400, an eleventh conductive pattern 412, the ninth insulating interlayer 870 and the ninth conductive pattern 880.

The second substrate 380 may include first and second regions I and II that may be aligned with the first and second region I and II of the third substrate 600. The second substrate 380 may include a semiconductor material, e.g., silicon or an insulating material, e.g., glass.

The tenth insulating interlayer 390 may be disposed on the second substrate 380. The third adhesion layer 1400 may cover an upper surface of the tenth insulating interlayer 390. The tenth insulating interlayer 390 may include an oxide, e.g., silicon oxide. The third adhesion layer 1400 may include, e.g., silicon oxide, silicon carbonitride, etc.

The eleventh conductive pattern 412 may extend through the third adhesion layer 1400 and the tenth insulating interlayer 390 and may contact an upper surface of the second substrate 380 on the first region I of the second substrate 380.

The ninth insulating interlayer 870 may cover an upper surface of the third adhesion layer 1400. The ninth insulating interlayer 870 may include an oxide, e.g., silicon oxide.

The ninth conductive pattern 880 may extend through the ninth insulating interlayer 870 and may contact a lower surface of the third wiring 860 and an upper surface of the eleventh conductive pattern 412 on the first region I of the second substrate 380.

The transistor layer TL may further include an eleventh insulating interlayer 900 and a first through via structure 950.

The eleventh insulating interlayer 900 may cover the second main surface S2 of the third substrate 600.

The first through via structure 950 may extend through the eleventh insulating interlayer 900, the third substrate 600 and the first insulating interlayer 670 and may contact the seventh conductive patterns (e.g., the first wirings 650). The first through via structure 950 may extend through the first and second main surfaces S1 and S2 of the third substrate 600.

In example embodiments, the first through via structure 950 may include a first through via 940 extending through the eleventh insulating interlayer 900, the third substrate 600 and the first insulating interlayer 670, and a third division pattern 930 covering a sidewall of the first through via 940.

The hydrogen diffusion path HDP may include a twelfth conductive pattern 414, the tenth conductive pattern 885, the fifth wiring 865, the second contact plug structure, the sixth conductive pattern 495, the second bonding pad structure, the second wiring structure 725, the eighth conductive patterns (e.g., the second wirings 655) and the second through via structure 955.

The twelfth conductive pattern 414 may be disposed on the second region II of the second substrate 380, and may be disposed at the same vertical level as the eleventh conductive pattern 412. The twelfth conductive pattern 414 may extend through the third adhesion layer 1400 and the tenth insulating interlayer 390 and may contact an upper surface of the second substrate 380. In example embodiments, the twelfth conductive pattern 414 may include substantially the same material as the eleventh conductive pattern 412.

The tenth conductive pattern 885 may be disposed on the second region II of the third substrate 600, and may be disposed at the same vertical level as the ninth conductive pattern 880. The tenth conductive pattern 885 may extend through the ninth insulating interlayer 870 and may contact a lower surface of the fifth wiring 865 and an upper surface of the twelfth conductive pattern 414. In example embodiments, the tenth conductive pattern 885 may include substantially the same material as the ninth conductive pattern 880.

The fifth wiring 865 may be disposed on the second region II of the second substrate 380, and may be disposed at the same vertical level as the third wiring 860. The fifth wiring 865 may contact a lower surface of the second contact plug structure. In example embodiments, the fifth wiring 865 may include substantially the same material as the third wiring 860.

In example embodiments, the fifth wiring 865 may be spaced apart from the fourth wiring 863 by the second division pattern 864. The second division pattern 864 may include an oxide, e.g., silicon oxide.

The second through via structure 955 may be disposed on the second region II of the second substrate 380, and may be disposed at the same vertical level as the first through via structure 950. The second through via structure 955 may extend through the eleventh insulating interlayer 900, the third substrate 600 and the first insulating interlayer 670 and may contact the eighth conductive patterns (e.g., the second wirings 655). The second through via structure 955 may extend through the first and second main surfaces S1 and S2 of the third substrate 600.

In example embodiments, the second through via structure 955 may include a second through via 945 extending through the eleventh insulating interlayer 900, the third substrate 600 and the first insulating interlayer 670, and a fourth division pattern 935 covering a sidewall of the second through via 945. In example embodiments, the second through via 945 and the fourth division pattern 935 may include substantially the same materials as the first through via 940 and the third division pattern 930, respectively.

Hydrogen may move to the channel 125 through the hydrogen diffusion path HDP, the second substrate 380, the eleventh conductive pattern 412, the ninth conductive pattern 880, the third wiring 860, the seventh contact plug 852, the plate electrode 230 and the capacitor structure 220. That is, hydrogen passivation with respect to the channel 125 may be performed through the second substrate 380.

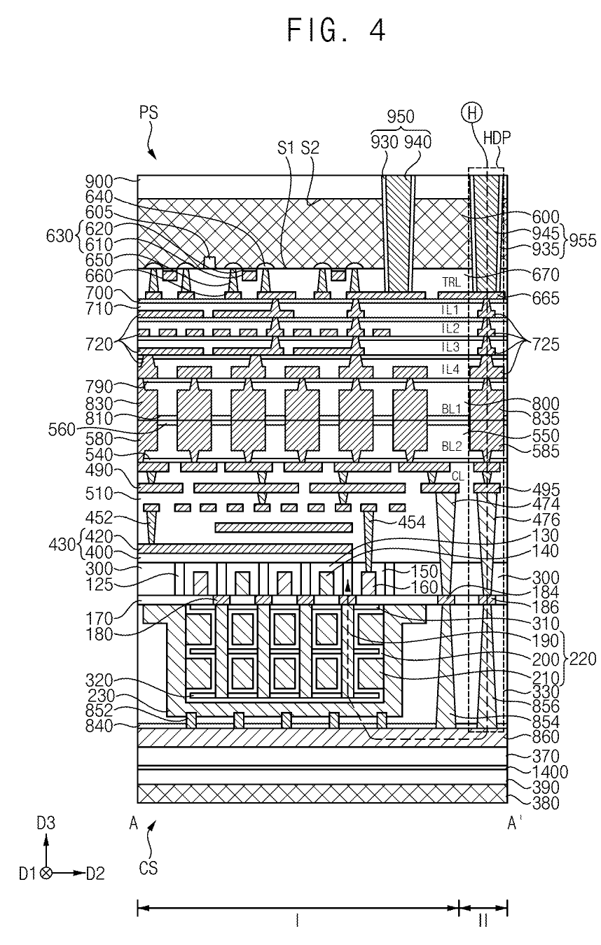

FIG. 4 is a cross-sectional view illustrating a semiconductor device in accordance with example embodiments, which may correspond to FIG. 3. This semiconductor device may be substantially the same as or similar to that of FIG. 3, except for some elements, and thus repeated explanations are omitted herein.

Referring to FIG. 4, the semiconductor device may not include the ninth to twelfth conductive patterns 880, 885, 412 and 414, the fifth wiring 865, and the first and second division patterns 862 and 864.

Hydrogen may move to the channel 125 through the hydrogen diffusion path HDP, the third wiring 860, the seventh contact plug 852, the plate electrode 230 and the capacitor structure 220. That is, hydrogen passivation with respect to the channel 125 may be performed through the third wiring 360.

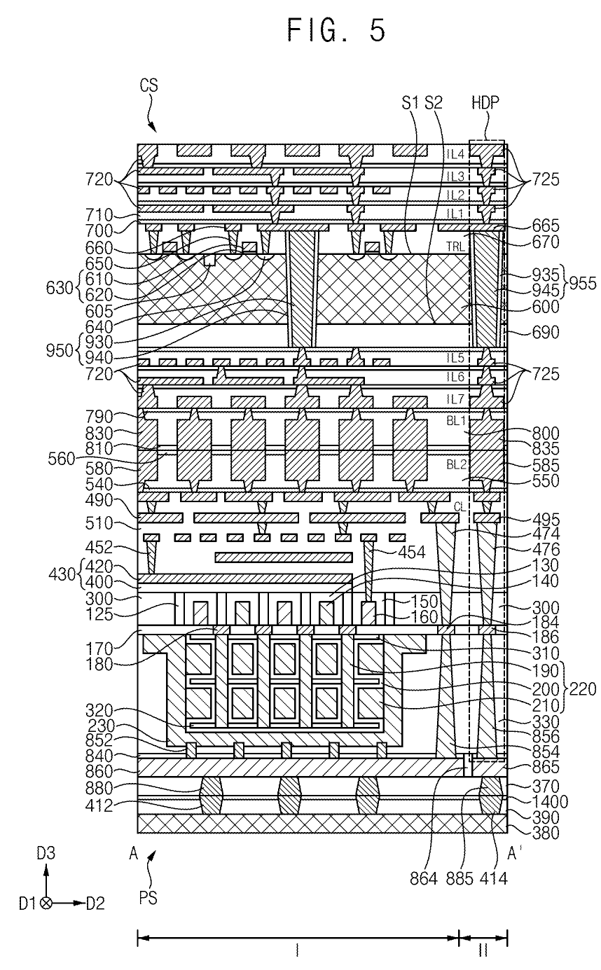

FIG. 5 is a cross-sectional view illustrating a semiconductor device in accordance with example embodiments, which may correspond to FIG. 3. This semiconductor device may be substantially the same as or similar to that of FIG. 3, except for some elements, and thus repeated explanations are omitted herein.

Referring to FIG. 5, the semiconductor device may have a back-to-back structure in which a distance between the bit line structure 430 and the second main surface S2 of the third substrate 600 is less than a distance between the capacitor structure 220 and the second main surface S2 of the third substrate 600.

The wiring layers IL1, IL2, …, ILn may be disposed not only on the first main surface S1 of the third substrate 600 but also on the second main surface S2 of the third substrate 600. FIG. 5 shows that three wiring layers IL1, IL2, IL3 and IL4 are disposed on the first main surface S1 of the third substrate 600 and three wiring layers IL5, IL6 and IL7 are disposed on the second surface S2 of the third substrate 600, however, the inventive concept is not limited thereto.

The hydrogen diffusion path HDP may extend through the wiring layers IL1, IL2, IL3 and IL4, the transistor layer TRL, the third substrate 600, the wiring layers IL5, IL6 and IL7, the first and second bonding layers BL1 and BL2 and the memory cell layer CL.

In example embodiments, the hydrogen diffusion path HDP may include the fifth wiring 865, the second contact plug structure, the sixth conductive pattern 495, the second bonding pad structure, the second wiring structure 725, the second through via structure 955, and the eighth conductive patterns (e.g., the second wirings 655).

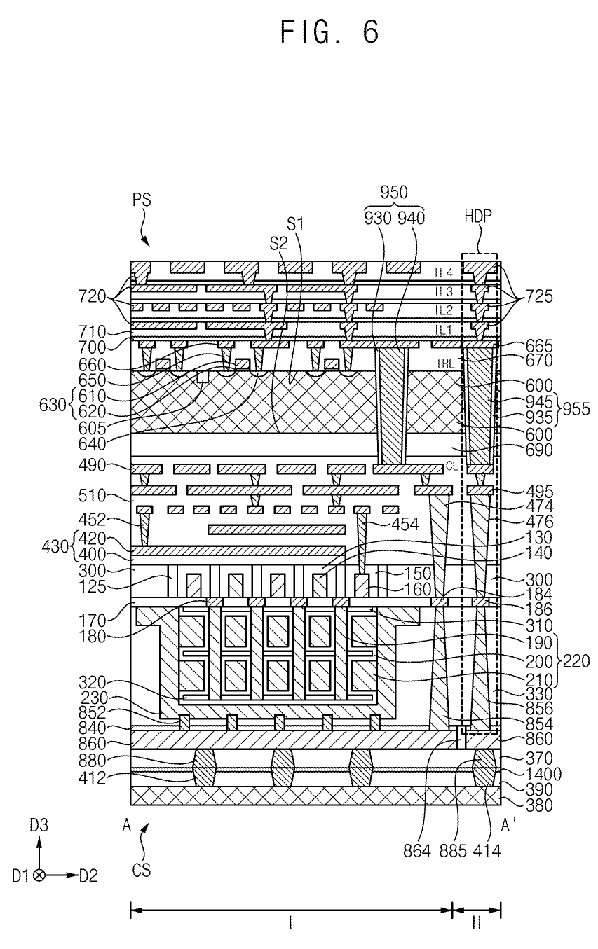

FIG. 6 is a cross-sectional view illustrating a semiconductor device in accordance with example embodiments, which may correspond to FIG. 5. This semiconductor device may be substantially the same as or similar to that of FIG. 5, except for some elements, and thus repeated explanations are omitted herein.

Referring to FIG. 6, the semiconductor device may not include the first and second bonding layers BL1 and BL2.

That is, the first and second through via structures 950 and 955 may directly contact the fifth and sixth conductive patterns 490 and 495, without passing through the first and second bonding pad structures, to be electrically connected to the cell structure CS.

In example embodiments, the first and second through via structures 950 and 955 may extend through an upper portion of the memory cell layer CL, and may contact the fifth and sixth conductive patterns 490 and 495.

The hydrogen diffusion path HDP may extend through the wiring layers IL1, IL2, …, ILn, the transistor layer TRL, the third substrate 600, the twelfth insulating interlayer 690 and the memory cell layer CL.

In example embodiments, the hydrogen diffusion path HDP may include the fifth wiring 865, the second contact plug structure, the sixth conductive pattern 495, the second through via structure 955, the eighth conductive patterns (e.g., the second wirings 655) and the second wiring structure 725.

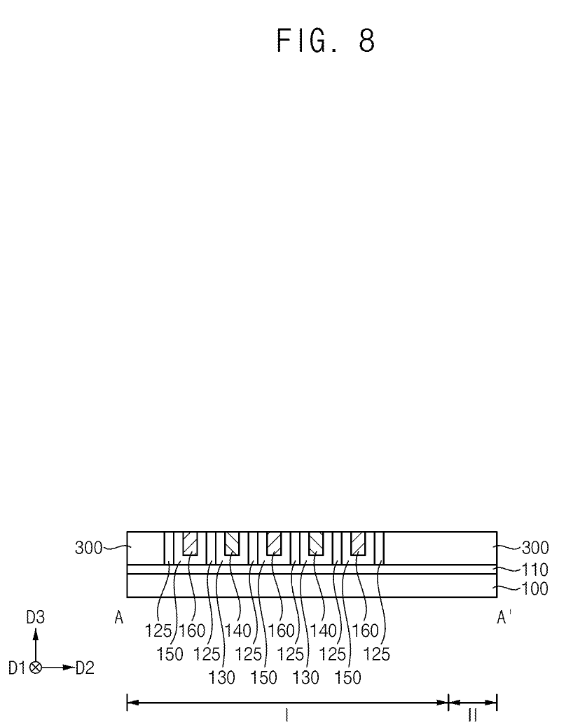

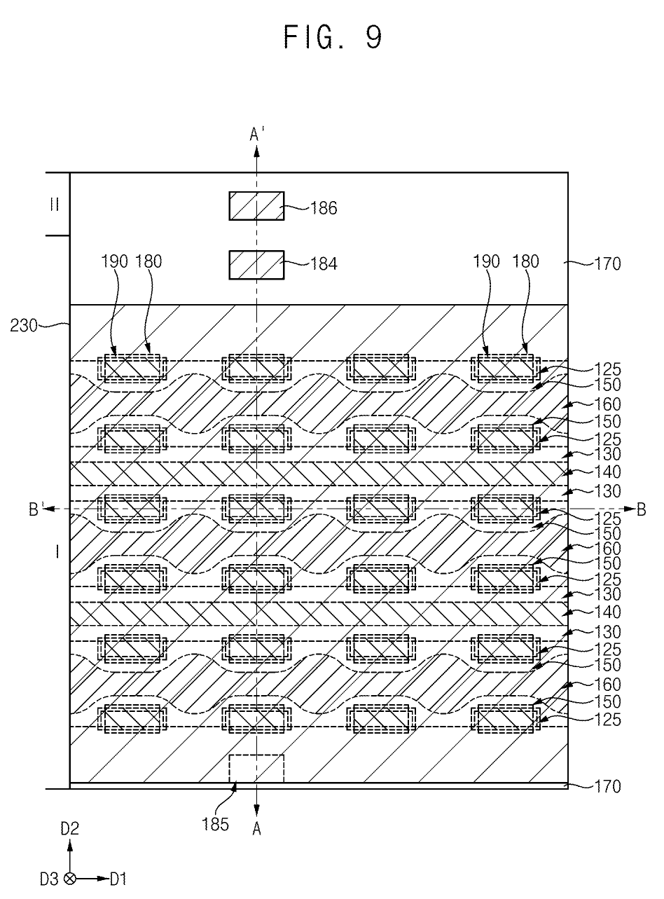

FIGS. 7-15 are plan views and cross-sectional views illustrating a method of manufacturing a semiconductor device in accordance with example embodiments. Specifically, FIGS. 7 and 9 are the plan views, and FIG. 8 and 10-15 are cross-sectional views taken along lines A-A’ of corresponding plan views, respectively.

Referring to FIGS. 7 and 8, a first substrate structure including a first bulk substrate 100, a buried oxide layer 110 and a second bulk substrate may be provided, and the second bulk substrate may be patterned to form a preliminary channel.

The first substrate structure may include first and second regions I and II.

In example embodiments, the preliminary channel may extend in the first direction D1, and a plurality of preliminary channels may be spaced apart from each other in the second direction D2. A first opening may be formed between ones of the preliminary channels neighboring in the second direction D2 to expose an upper surface of the buried oxide layer 110.

A first gate insulation layer may be formed on the preliminary channel and the buried oxide layer 110, an anisotropic etching process may be performed on the first gate insulation layer to remove a portion of the first gate insulation layer on an upper surface of the preliminary channel. Thus, a first gate insulation pattern 130 may be formed on a sidewall of the first opening and the upper surface of the buried oxide layer 110. In example embodiments, the first gate insulation pattern 130 may contact opposite sidewalls in the second direction D2 of respective ones of the preliminary channels neighboring in the second direction D2 and an upper surface of a portion of the buried oxide layer 110 between the neighboring ones of the preliminary channels, and may extend in the first direction D1.

A first gate electrode layer may be formed on the preliminary channel and the first gate insulation pattern 130, and a planarization process may be performed on the first gate electrode layer until upper surfaces of the preliminary channel and the first gate insulation pattern 130 are exposed to form a first gate electrode 140. The planarization process may include, e.g., a chemical mechanical polishing (CMP) process and/or an etch back process.

The first gate electrode 140 and the first gate insulation pattern 130 may collectively form a first gate structure. In example embodiments, the first gate structure may extend in the first direction D1, and a plurality of first gate structures may be spaced apart from each other in the second direction D2.

The preliminary channel, the first gate insulation pattern 130 and the first gate electrode 140 on the second region II of the first substrate structure may be partially removed to form a second opening exposing the upper surface of the buried oxide layer 110, and a sixth insulating interlayer 300 may be formed in the second opening.

The preliminary channel may be patterned to form a channel 125.

In example embodiments, a plurality of channels 125 may be spaced apart from each other in the first direction D1 on a sidewall in the second direction D2 of the first gate insulation pattern 130 extending in the first direction D1. A third opening may be formed between ones of the channels 125 that are disposed between ones of the first gate insulation patterns 130 neighboring in the second direction D2, and may expose the upper surface of the buried oxide layer 110.

A second gate insulation layer may be formed on the channel 125, the first gate insulation pattern 130, the first gate electrode 140 and the buried oxide layer 110, and a portion of the second gate insulation layer on upper surfaces of the channel 125, the first gate insulation pattern 130 and the first gate electrode 140 may be removed by, e.g., an anisotropic etching process to form a second gate insulation pattern 150.

In example embodiments, the second gate insulation pattern 150 may contact opposite sidewalls in the second direction D2 of ones of the first gate insulation patterns 130 neighboring in the second direction D2, opposite sidewalls in the second direction D2 of ones of the channels 125 neighboring in the second direction D2, an upper surface of a portion of the buried oxide layer 110 between the neighboring ones of the first gate insulation patterns 130 and an upper surface of a portion of the buried oxide layer 110 between the neighboring ones of the channels 125.

A second gate electrode layer may be formed on the channel 125, the first and second gate insulation patterns 130 and 150, the first gate electrode 140 and the sixth insulating interlayer 300, and a planarization process may be performed on the second gate electrode layer until upper surfaces of the channel 125, the first and second gate insulation patterns 130 and 150, the first gate electrode 140 and the sixth insulating interlayer 300 are exposed to form a second gate electrode 160. The planarization process may include a CMP process and/or an etch back process.

The second gate electrode 160 and the second gate insulation pattern 150 may collectively form a second gate structure. In example embodiments, the second gate structure may extend in the first direction D1, and a plurality of second gate structures may be spaced apart from each other in the second direction D2.

In example embodiments, the second gate electrode 160 may include an extension portion straightly extending in the first direction D1 and protrusion portions protruding from the extension portion in the second direction D2 and being spaced apart from each other in the first direction D1, in a plan view.

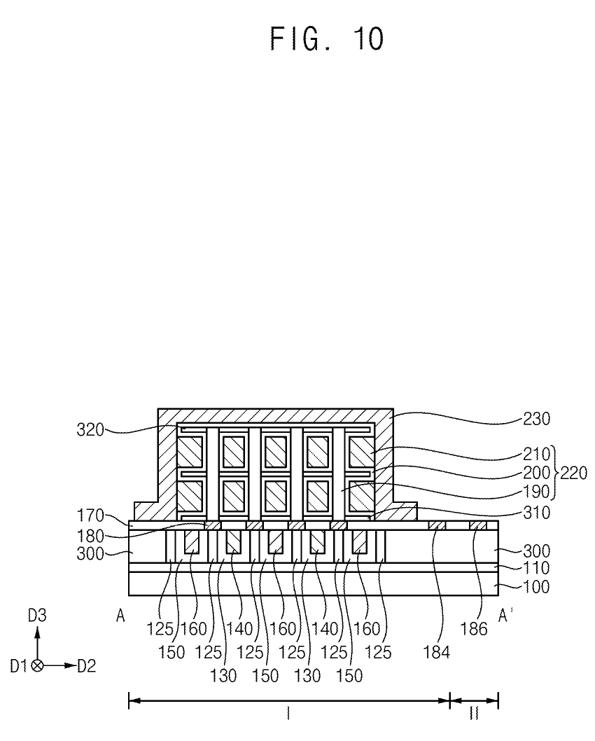

Referring to FIGS. 9 and 10, a seventh insulating interlayer 170 may be formed on the first and second gate structures and the sixth insulating interlayer 300, and first to third conductive pads 180, 184 and 186 may be formed through the seventh insulating interlayer 170.

In example embodiments, a plurality of first conductive pads 180 may be spaced apart from each other in each of the first and second directions D1 and D2 to contact respective upper surfaces of the channels 125. Each of the second and third conductive pads 184 and 186 may extend through a portion of the seventh insulating interlayer 170 on the sixth insulating interlayer 300.

A capacitor structure 220 and a plate electrode 230 may be formed on the seventh insulating interlayer 170 and the first conductive pad 180. The capacitor structure 220 and the plate electrode 230 may be formed by, e.g., following processes.

A fourth etch stop layer 310 may be formed on the seventh insulating interlayer 170 and the first to third conductive pads 180, 184 and 186, and a mold layer and a support layer 320 may be alternately and repeatedly formed on the fourth etch stop layer 310. The fourth etch stop layer 310 may include an insulating nitride, e.g., silicon boronitride, the mold layer may include an oxide, e.g., silicon oxide, and the support layer 320 may include an insulating nitride, e.g., silicon nitride.

A fourth opening may be formed through the support layers 320, the mold layers and the fourth etch stop layer 310 to expose an upper surface of the first conductive pad 180, a first capacitor electrode layer may be formed on the upper surface of the first conductive pad 180 and an upper surface of an uppermost one of the support layers 320, and a planarization process may be performed on the first capacitor electrode layer until the upper surface of an uppermost one of the support layers 320 is exposed to form a first capacitor electrode 190 in the fourth opening.

The planarization process may include, e.g., a CMP process and/or an etch back process.

The support layers 320 and the mold layers may be partially removed to form a fifth opening exposing an upper surface of the fourth etch stop layer 310, and the mold layers may be removed through the fifth opening.

In example embodiments, the mold layers may be removed by a wet etching process, and as the wet etching process is performed, a sixth opening may be formed to expose a sidewall of the first capacitor electrode 190 and the upper surface of the fourth etch stop layer 310. However, the support layers 320 may remain on the sidewall of each of the first capacitor electrodes 190, and thus a surface of each of the support layers 320 may be exposed by the sixth opening.

A dielectric layer 200 may be formed on the sidewall of each of the first capacitor electrodes 190, the upper surface of the fourth etch stop layer 310 and the surface of each of the support layers 320 exposed by the sixth opening, and a second capacitor electrode layer may be formed on the dielectric layer 200 to fill the sixth opening. The dielectric layer 200 and the second capacitor electrode layer may also be formed on an upper surface of the first capacitor electrode 190 and the upper surface of the uppermost one of the support layers 320.

For example, a wet etching process may be performed on the second capacitor electrode layer to form a second capacitor electrode 210 in the sixth opening. The first capacitor electrode 190, the dielectric layer 200 and the second capacitor electrode 210 may collectively form a capacitor structure 220.

A plate electrode 230 may be formed on an upper surface and a sidewall of the capacitor structure 220 and an upper surface of the seventh insulating interlayer 170.

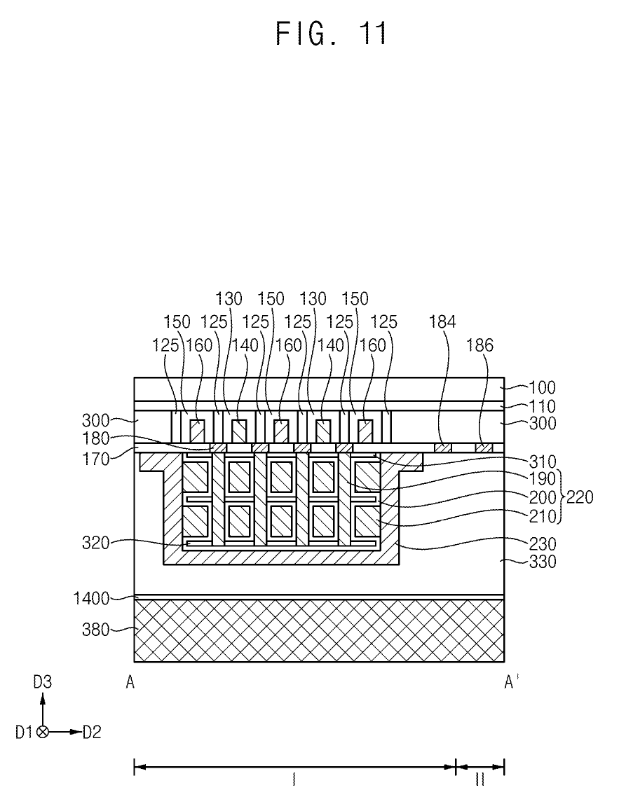

Referring to FIG. 11, an eighth insulating interlayer 330 may be formed on the plate electrode 230, the seventh insulating interlayer 170 and the second and third conductive pads 184 and 186, and a second substrate 380 may be bonded with an upper surface of the eighth insulating interlayer 330 with a third adhesion layer 1400 therebetween.

The second substrate 380 may include first and second regions I and II corresponding to those of the first substrate structure. The second substrate 380 may include a semiconductor material, e.g., silicon, or an insulating material, e.g., glass. The third adhesion layer 1400 may include, e.g., silicon carbonitride, silicon oxide, etc.

A structure including the first substrate structure and the second substrate 380 may be flipped so that top and bottom of the structure may be reversed. Thus, following explanation is based on the reversed direction.

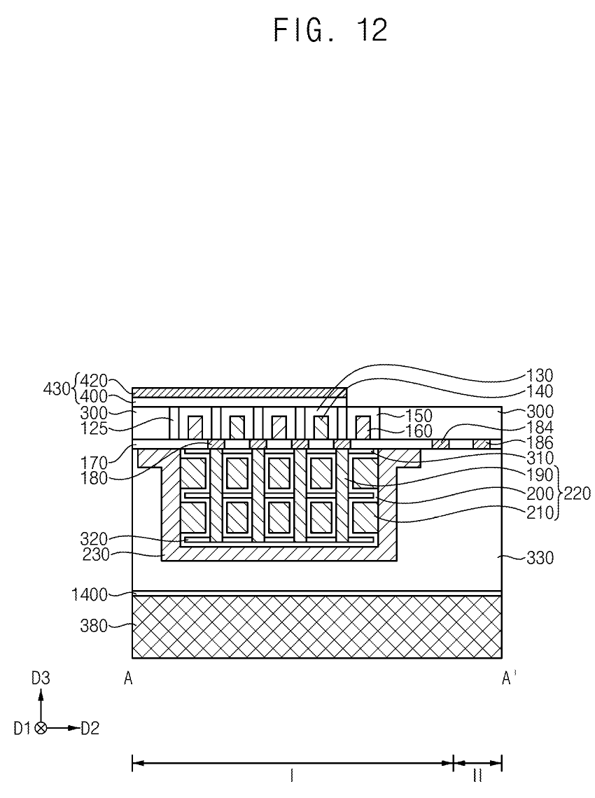

Referring to FIG. 12, the first bulk substrate 100 and the buried oxide layer 110 included in the first substrate structure may be removed by, e.g., a grinding process, and thus upper surfaces of the channel 125, the first and second gate insulation patterns 130 and 150 and the sixth insulating interlayer 300 may be exposed.

A bit line structure 430 may be formed on the upper surfaces of the channel 125, the first and second gate insulation patterns 130 and 150 and the sixth insulating interlayer 300. In example embodiments, the bit line structure 430 may extend in the second direction D2, and a plurality of bit line structures 430 may be spaced apart from each other in the first direction D1. Each of the bit line structures 430 may contact the upper surfaces of the channels 125 disposed in the second direction D2.

In an example embodiment, each of the bit line structures 430 may include third and fourth conductive patterns 400 and 420 stacked in the third direction D3, which may include, e.g., doped polysilicon and a metal, respectively.

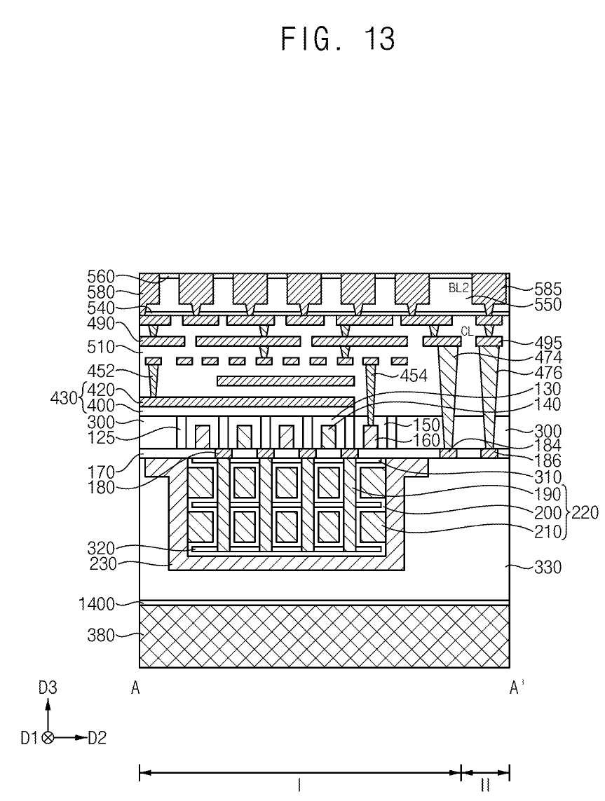

Referring to FIG. 13, third to sixth contact plugs 452, 454, 474 and 476, a fifth conductive pattern 490 and a sixth conductive pattern 495 may be formed on the bit line structure 430, and a fifth insulating interlayer 510 may be formed on the channel 125, the first and second gate insulation patterns 130 and 150 and the sixth insulating interlayer 300.

In example embodiments, the third to fifth contact plugs 452, 454 and 474 and the fifth conductive pattern 490 may be formed on the first region I of the second substrate 380. In example embodiments, the sixth contact plug 476 and the sixth conductive pattern 495 may be formed on the second region II of the second substrate 380.

In example embodiments, the sixth contact plug 476 may be formed by the same process of forming the fifth contact plug 474, and may be formed at the same vertical level as the fifth contact plug 474.

In example embodiments, the sixth conductive pattern 495 may be formed by the same process of forming the fifth conductive pattern 490, and may be formed at the same vertical level as the fifth conductive pattern 490.

In example embodiments, each of the third to sixth contact plugs 452, 454, 474, 476 may have a width gradually decreasing from a top toward a bottom thereof.

A second bonding layer BL2 and a fourth bonding pad 585 may be formed on the fifth insulating interlayer 510, the fifth conductive pattern 490 and the sixth conductive pattern 495. The second bonding layer BL2 may include a third etch stop layer 540, a fourth insulating interlayer 550, a second adhesion layer 560 and a third bonding pad 580.

The third etch stop layer 540 may cover an upper surface of the memory cell layer CL. The fourth insulating interlayer 550 may be formed on the third etch stop layer 540. The second adhesion layer 560 may be formed to cover an upper surface of the fourth insulating interlayer 550.

The third bonding pad 580 may extend through the second adhesion layer 560, the fourth insulating interlayer 550 and the third etch stop layer 540 and may contact an upper surface of the fifth conductive pattern 490. The fourth bonding pad 585 may extend through the second adhesion layer 560, the fourth insulating interlayer 550 and the third etch stop layer 540 and may contact an upper surface of the sixth conductive pattern 495.

In example embodiments, the fourth bonding pad 585 may be formed by the same process of forming the third bonding pad 580, and may be disposed at the same vertical level as the third bonding pad 580.

In example embodiments, each of the third and fourth bonding pads 580 and 585 may include a lower portion and an upper portion that is disposed on the lower portion and has a width greater than that of the lower portion.

In example embodiments, the third and fourth bonding pads 580 and 585 may be formed by forming a first trench through the second adhesion layer 560, the fourth insulating interlayer 550 and the third etch stop layer 540, forming a third bonding pad layer to fill the first trench, and performing a planarization process on the third bonding pad layer until an upper surface of the second adhesion layer 560 is exposed.

In example embodiments, the second adhesion layer 560 may include, e.g., silicon carbonitride. Each of the third and fourth bonding pads 580 and 585 may include, e.g., copper.

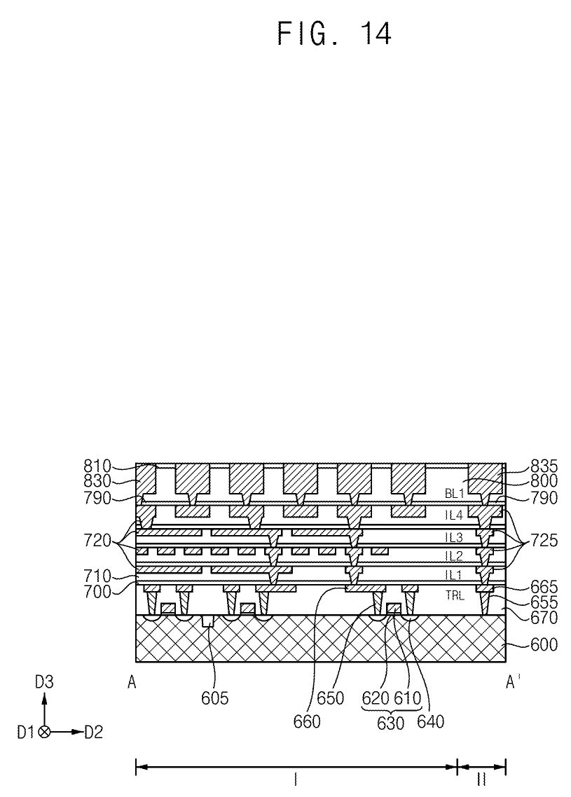

Referring to FIG. 14, a third gate structure 630 may be formed on a first region I of a third substrate 600 including the first region and a second region II, and impurity regions 640 may be formed at portions of the third substrate 600 adjacent to the third gate structure 630, so that a transistor including the third gate structure 630 and the impurity regions 640 may be formed on the first region I of the third substrate 600.

In example embodiments, a plurality of transistors may be formed to be spaced apart from each other in the horizontal direction on the first region I of the third substrate 600.

Seventh conductive patterns (e.g., a first contact plug 650, a first wiring 660, etc.) may be formed on the first region I of the third substrate 600. Eighth conductive patterns (e.g., a second contact plug 655, a second wiring 665, etc.) may be formed on the second region II of the third substrate 600.

In example embodiments, the eighth conductive patterns may be formed by the same process of forming corresponding ones of the seventh conductive patterns, and may be disposed at the same vertical levels as those of the corresponding ones of the seventh conductive patterns.

A first insulating interlayer 670 may be formed on the third substrate 600 to cover the transistor and the seventh and eighth conductive patterns.

The transistor and the seventh and eighth conductive patterns may form a transistor layer TRL.

Wiring layers IL1, IL2, …, ILn and a second wiring structure 725 may be formed on the transistor layer TRL. FIG. 14 shows that four wiring layers IL1, IL2, IL3 and IL4 are formed, however, the inventive concept is not limited thereto. Hereinafter, for convenience of explanation, an arbitrary wiring layer Ili among the wiring layers IL1, IL2, … , ILn is described.

The wiring layer ILi may include a first etch stop layer 700, a second insulating interlayer 710 and first wiring structures 720.

The first etch stop layer 700 may cover an upper surface of the transistor layer TRL or an upper surface of a lower one IL(i-1) of the wiring layers IL1, IL2, … , ILn. The second insulating interlayer 710 may be formed on the first etch stop layer 700.

The first wiring structures 720 of the wiring layer ILi may extend through the second insulating interlayer 710 and the first etch stop layer 700 of the wiring layer ILi and may contact the seventh conductive patterns of the transistor layer TRL, or the first wiring structures 720 of the lower one IL(i-1) of the wiring layers IL1, IL2, … , ILn.

The second wiring structures 725 of the wiring layer ILi may extend through the second insulating interlayer 710 and the first etch stop layer 700 of the wiring layer ILi and may contact the seventh conductive patterns of the transistor layer TRL, or the second wiring structures 725 of the lower one IL(i-1) of the wiring layers IL1, IL2, … , ILn.

In example embodiments, the second wiring structures 725 may be formed by the same process of forming corresponding ones of the first wiring structures 720, and may be disposed at the same vertical level as those of the corresponding ones of the first wiring structures 720.

In example embodiments, each of the first and second wiring structures 720 and 725 may include a plug portion and a wiring portion that is disposed on the plug portion and connected to the plug portion.

The first and second wiring structures 720 and 725 may be formed by, e.g., a single damascene process or a dual damascene process. FIG. 14 shows that each of the first and second wiring structures 720 and 725 is formed by the dual damascene process, however, the inventive concept is not limited thereto. For example, each of the first and second wiring structures 720 and 725 may be formed by performing a single damascene process twice so that the plug portion and the wiring portion may be independently formed.

A first bonding layer BL1 and a second bonding pad 835 may be formed on an uppermost one of the wiring layers IL1, IL2, … , ILn.

The first bonding layer BL1 may include a second etch stop layer 790, a third insulating interlayer 800, a first adhesion layer 810 and a first bonding pad 830.

The second etch stop layer 790 may cover an upper surface of the uppermost one ILn of the wiring layers IL1, IL2, … , ILn. The third insulating interlayer 800 may be formed on the second etch stop layer 790. The first adhesion layer 810 may cover an upper surface of the third insulating interlayer 800.

The first bonding pad 830 may be formed through the first adhesion layer 810, the third insulating interlayer 800 and the second etch stop layer 790 to contact an upper surface of the first wiring structure 720 of the uppermost one ILn of the wiring layers IL1, IL2, … , ILn. The second bonding pad 835 may be formed through the first adhesion layer 810, the third insulating interlayer 800 and the second etch stop layer 790 to contact an upper surface of the second wiring structure 725 of the uppermost one ILn of the wiring layers IL1, IL2, … , ILn.

In example embodiments, the second bonding pad 835 may be formed by the same process of forming the first bonding pad 830, and may be disposed at the same vertical level as the first bonding pad 830.

In example embodiments, each of the first and second bonding pads 830 and 835 may include a lower portion and an upper portion that is disposed on the lower portion and has a width greater than that of the lower portion.

In example embodiments, the first and second bonding pads 830 and 835 may be formed by forming a second trench through the first adhesion layer 810 and the fourth insulating interlayer 800, forming a first bonding pad layer to fill the second trench, and performing a planarization process, e.g., a CMP process on the first bonding pad layer until an upper surface of the first adhesion layer 810.

In example embodiments, the first adhesion layer 810 may include, e.g., silicon carbonitride, and each of the first and second bonding pads 830 and 835 may include, e.g., copper.

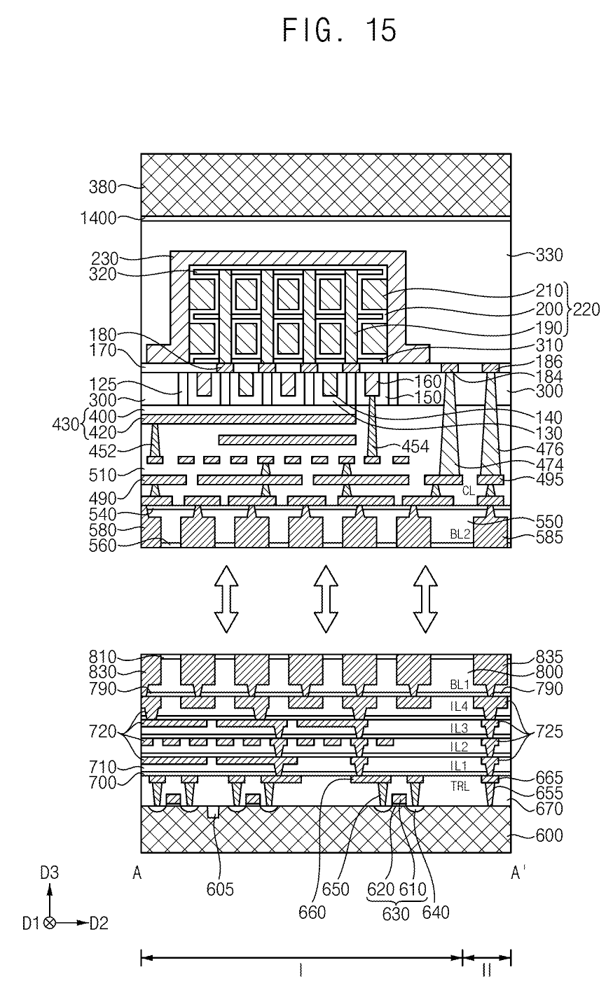

Referring to FIG. 15, a structure shown in FIG. 13 and a structure shown in FIG. 14 may be bonded to each other.

Particularly, after flipping the second substrate 380, the structure beneath the second substrate 380 and the structure on the third substrate 600 may be bonded to each other such that the first and second regions I and II of the second substrate 380 may be aligned to the first and second regions I and II, respectively, of the third substrate 600. The first and second adhesion layers 810 and 560 may be bonded to each other to form an adhesion layer structure. The first and third bonding pads 820 and 580 may be bonded to each other to form a first bonding pad structure, and the second and fourth bonding pads 830 and 580 may be bonded to each other to form a second bonding pad structure.

Referring to FIG. 1 again, the third adhesion layer 1400 and the second substrate 380 may be removed from the eighth insulating interlayer 330, a fifth etch stop layer 840 may be formed on the eighth insulating interlayer 330, and a seventh contact plug 852 extending through the fifth etch stop layer 840 and the eighth insulating interlayer 330 to contact an upper surface of the plate electrode 230 and eighth and ninth contact plugs 854 and 856 extending through the fifth etch stop layer 840 and the eighth insulating interlayer 330 to contact upper surfaces of the second and third conductive pads 184 and 186, respectively, may be formed.

In example embodiments, the ninth contact plug 856 may be formed by the same process of forming the eighth contact plug 854, and may be disposed at the same vertical levels as the eighth contact plug 854.

A third wiring 860 may be formed on the fifth etch stop layer 840 to contact the seventh to ninth contact plugs 852, 854 and 856 so as to manufacture the semiconductor device.

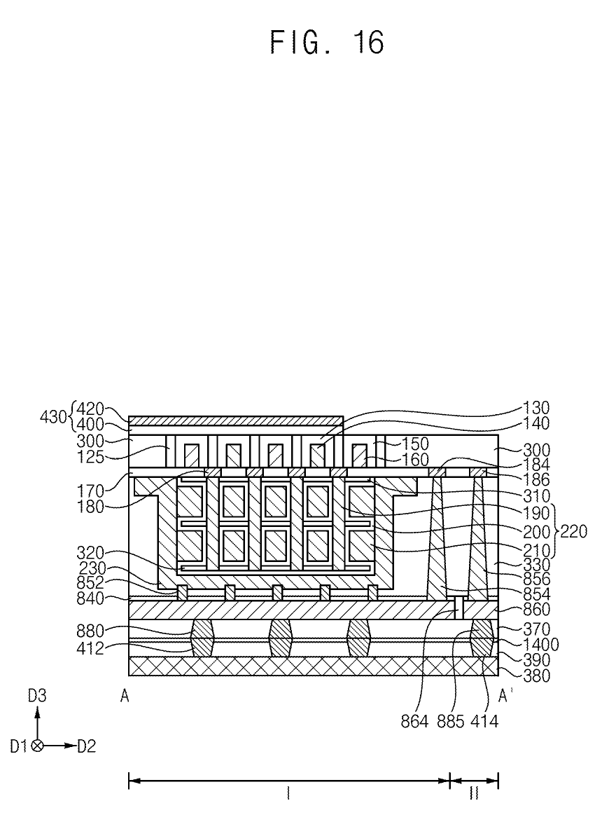

FIGS. 16-20 are cross-sectional views illustrating a method of manufacturing a semiconductor device in accordance with example embodiments. Specifically, FIGS. 16-20 are cross-sectional views taken along lines A-A’ of corresponding plan views, respectively.

This method may include processes substantially the same as or similar to those illustrated with reference to FIGS. 7-15 and 1, and thus repeated explanations thereof are omitted herein.

Referring to FIG. 16, processes substantially the same as or similar to those illustrated with reference to FIG. 11 may be performed.

However, unlike those of FIG. 11, the fifth etch stop layer 840 may be formed on the eighth insulating interlayer 330, and the seventh contact plug 852 contacting the upper surface of the plate electrode 230 and the eighth and ninth contact plugs 854 and 856 contacting the upper surfaces of the second and third conductive pads 184 and 186, respectively, may be formed.

The third and fourth wirings 860 and 865 may be formed on the fifth etch stop layer 840 to contact the upper surfaces of the seventh to ninth contact plugs 852, 854 and 856, and the second division pattern 864 may be formed to separate the third and fourth wirings 860 and 865 from each other.

The tenth insulating interlayer 370 may be formed on the third and fourth wirings 860 and 865, and the ninth and tenth conductive patterns 880 and 885 may be formed through the tenth insulating interlayer 370 to contact the third and fourth wirings 860 and 865, respectively.

The eleventh insulating interlayer 390 and the third adhesion layer 1400 may be sequentially formed on the second substrate 380, and the eleventh and twelfth conductive patterns 412 and 414 may be formed through the eleventh insulating interlayer 390 and the third adhesion layer 1400 to contact the upper surface of the second substrate 380.

The second substrate 380 may be bonded to an upper surface of the tenth insulating interlayer 370 through the third adhesion layer 1400. The eleventh and twelfth conductive patterns 412 and 414 may contact the ninth and tenth conductive patterns 880 and 885, respectively.

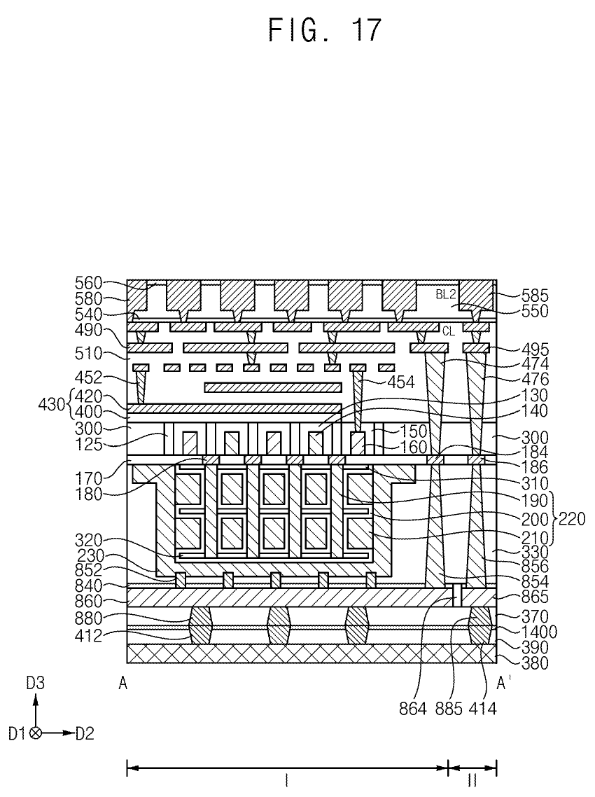

Referring to FIG. 17, processes substantially the same as or similar to those illustrated with reference to FIG. 13 may be performed.

That is, the third to sixth contact plugs 452, 454, 474 and 476, the fifth conductive pattern 490 and the sixth conductive pattern 495 may be formed on the bit line structure 430, and the fifth insulating interlayer 510 may be formed to cover the third to sixth contact plugs 452, 454, 474 and 476, the fifth conductive pattern 490 and the sixth conductive pattern 495.

The second bonding layer BL2 and the fourth bonding pad 585 may be formed on the fifth insulating interlayer 510, the fifth conductive pattern 490 and the sixth conductive pattern 495.

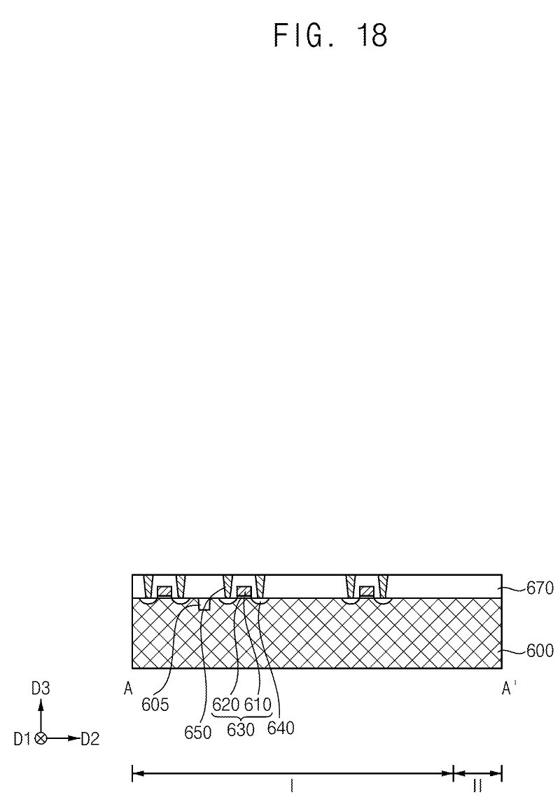

Referring to FIG. 18, processes substantially the same as or similar to those illustrated with reference to FIG. 14 may be performed to form a transistor including the third gate structure 630 and the impurity regions 640 on the first region I of the third substrate 600.

The seventh conductive patterns (e.g., the first contact plugs 650) may be formed on the first main surface S1 of the first region I of the third substrate 600. The first insulating interlayer 670 may cover the transistor and some of the seventh conductive patterns.

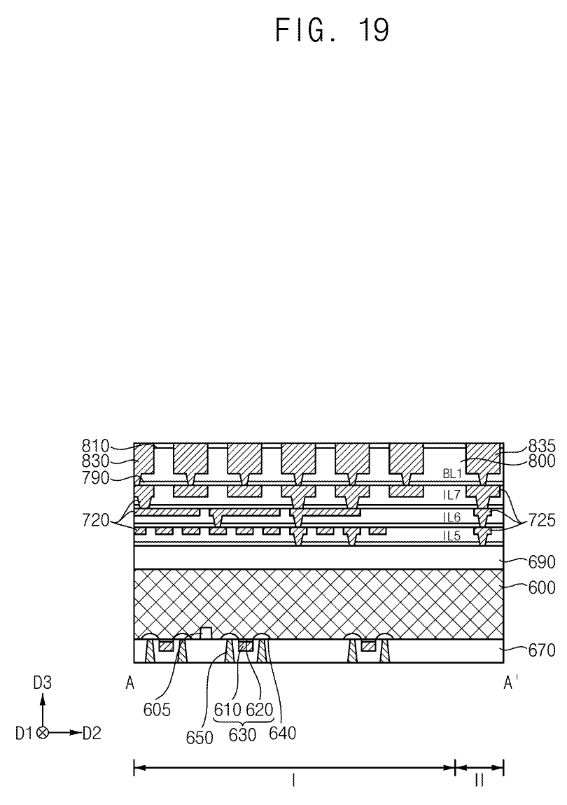

Referring to FIG. 19, after flipping the third substrate 600 so that the first main surface S1 may face downward, the twelfth insulating interlayer 690 may be formed on the second main surface S2 of the third substrate 600.

The wiring layers IL5, IL6 and IL7 may be formed on the twelfth insulating interlayer 690, and the second wiring structure 725 may be formed therethrough.

The first bonding layer BL1 and the second bonding pad 835 may be formed on the wiring layer IL7.

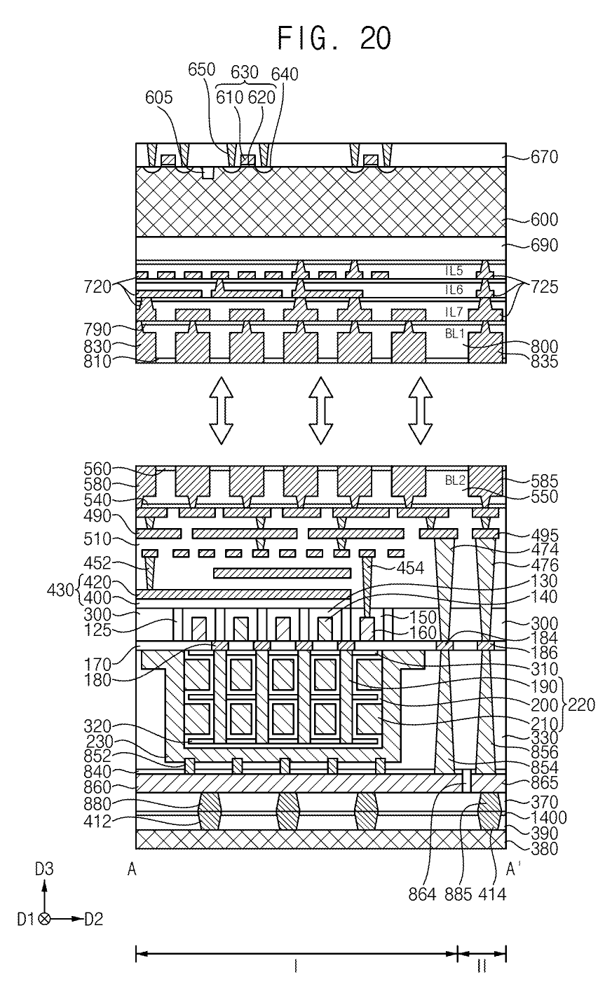

Referring to FIG. 20, processes substantially the same as or similar to those illustrated with reference to FIG. 15 may be performed so that a structure shown in FIG. 17 and a structure shown in FIG. 19 may be bonded to each other.

As top and bottom of the structure on the third substrate 600 may be reversed, following explanation is based on the reversed direction.

Referring to FIG. 5 again, the first and second through via structures 950 and 955 may be formed through the first insulating interlayer 670, the third substrate 600 and the twelfth insulating interlayer 690.

The first and second through via structures 950 and 955 may contact upper surfaces of the first and second wiring structures 720 and 725, respectively, in the wiring layer IL5.

The seventh conductive patterns and the first insulating interlayer covering the seventh conductive patterns may be formed, and the wiring layers IL1, IL2, IL3 and IL4 and the second wiring structure 725 may be formed to manufacture the semiconductor device.

In the method of manufacturing the semiconductor device, a cell structure may be formed. Particularly, a channel and a gate structure may be formed on a first region of a first substrate including the first region and a second region. A capacitor structure may be formed on a first end portion of the channel in a vertical direction perpendicular to an upper surface of the first substrate. The first substrate may be flipped. A bit line structure may be formed on a second end portion of the channel in the vertical direction. A first bonding pad and a second bonding pad may be formed on the first and second regions, respectively, of the first substrate. A peripheral circuit structure may be formed. Particularly, a transistor may be formed on a first region of a second substrate including the first region and a second region that may correspond to those of the first substrate. A first wiring structure and a second wiring structure may be formed on the first and second regions, respectively, of the second substrate. A third bonding pad and a fourth bonding pad may be formed on the first and second regions, respectively, of the second substrate. The peripheral circuit structure and the cell structure may be bonded to each other. A first contact plug structure and a second contact plug structure may be formed on the first and second regions, respectively, of the first substrate. The first and second contact plug structures may overlap the bit line structure, the channel and the capacitor structure in a horizontal direction parallel to the upper surface of the first substrate. The second wiring structure, the second bonding pad, the fourth bonding pad and the second contact plug structure may be sequentially stacked on the second region of the first substrate in the vertical direction and may form a hydrogen diffusion path.

In example embodiments, the second wiring structure, the second bonding pad, the fourth bonding pad and the second conductive plug structure of the hydrogen diffusion path may be disposed at the same vertical levels as those of the first wiring structure, the first bonding pad, the third bonding pad and the first contact plug structure, respectively.

In example embodiments, when the first and second contact plug structures are formed, after forming the capacitor structure and before flipping the first substrate, a first contact plug may be formed on the first region of the first substrate, and a second contact plug may be formed on the second region of the first substrate. The first and second contact plugs may overlap the capacitor structure in the horizontal direction. After forming the bit line structure and before forming the first and second bonding pads, a third contact plug may be formed on the first region of the first substrate to be electrically connected to the first contact plug, and a fourth contact plug may be formed on the second region of the first substrate to be electrically connected to the second contact plug. The third and fourth contact plugs may overlap the gate structure and the bit line structure in the horizontal direction. The first contact plug structure may include the first and third contact plugs, and the second contact plug structure may include the second and fourth contact plugs.

In the method, the second contact plug may be disposed at the same vertical level as the first contact plug, and the fourth contact plug may be disposed at the same vertical level as the third contact plug.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a transistor layer including a transistor on a first region of a substrate, the substrate including the first region and a second region;
a wiring layer on the transistor layer, the wiring layer including a first wiring structure on the first region of the substrate;
a bonding layer on the wiring layer, the bonding layer including a first bonding pad structure on the first region of the substrate;
a memory cell layer on the bonding layer; and
a hydrogen diffusion path extending through the memory cell layer, the bonding layer and the wiring layer on the second region of the substrate, the hydrogen diffusion path contacting an upper surface of the substrate and spaced apart from the transistor,
wherein on the first region, the memory cell layer includes:
a bit line structure;
a channel on the bit line structure;
a gate structure at a side of the channel on the bit line structure; and
a capacitor structure on the channel.

2. The semiconductor device according to claim 1, wherein a distance between the bit line structure and the upper surface of the substrate is less than a distance between the capacitor structure and the upper surface of the substrate.

3. The semiconductor device according to claim 1, wherein a distance between the capacitor structure and the upper surface of the substrate is less than a distance between the bit line structure and the upper surface of the substrate.

4. The semiconductor device according to claim 1, wherein the transistor layer further includes a first conductive pattern connected to the transistor, and
wherein the memory cell layer further includes a first contact plug structure overlapping the bit line structure, the channel and the capacitor structure in a horizontal direction parallel to the upper surface of the substrate.

5. The semiconductor device according to claim 4, wherein the hydrogen diffusion path includes a second conductive pattern, a second wiring structure, a second bonding pad structure and a second contact plug structure sequentially stacked in a vertical direction perpendicular to the upper surface of the substrate, and
wherein the second conductive pattern is disposed in the transistor layer, the second wiring structure extends through the wiring layer, the second bonding pad structure extends through the bonding layer, and the second contact plug structure at least partially extends through the memory cell layer.

6. The semiconductor device according to claim 5, wherein the second conductive pattern is disposed at the same vertical level as the first conductive pattern, the second wiring structure is disposed at the same vertical level as the first wiring structure, the second bonding pad structure is disposed at the same vertical level as the first bonding pad structure, and the second contact plug structure is disposed at the same vertical level as the first contact plug structure.

7. The semiconductor device according to claim 5, wherein:
the memory cell layer further includes a first conductive pad between the channel and the capacitor structure,
the first contact plug structure includes a first contact plug overlapping the bit line structure and the gate structure in the horizontal direction, a second conductive pad overlapping the first conductive pad in the horizontal direction, and a second contact plug overlapping the capacitor structure in the horizontal direction, and
the second contact plug structure includes a third contact plug overlapping the bit line structure and the gate structure in the horizontal direction, a third conductive pad overlapping the first conductive pad in the horizontal direction, and a fourth contact plug overlapping the capacitor structure in the horizontal direction.

8. A semiconductor device comprising:
a memory cell layer including:
a capacitor structure on a first region of a first substrate, the first substrate including the first region and a second region;
a channel on the capacitor structure;
a gate structure at a side of the channel on the capacitor structure;
a bit line structure on the channel; and
a first contact plug structure overlapping the capacitor structure, the channel and the bit line structure in a horizontal direction parallel to an upper surface of the first substrate;
a bonding layer on the memory cell layer, the bonding layer including a first bonding pad structure on the first region of the first substrate;
a wiring layer on the bonding layer, the wiring layer including a first wiring structure on the first region of the first substrate;
a second substrate on the wiring layer, the second substrate including a first main surface and a second main surface opposite to each other;
a transistor layer including a transistor and a first through via structure, the transistor being disposed on the first main surface of the second substrate on the first region of the first substrate, and the first through via structure extending through the first and second main surfaces of the second substrate on the first region of the first substrate; and
a hydrogen diffusion path spaced apart from the transistor and including a second contact plug structure, a second bonding pad structure, a second wiring structure and a second through via structure sequentially stacked on an upper surface of the second region of the first substrate in a vertical direction perpendicular to the upper surface of the first substrate,
wherein the second contact plug structure at least partially extends through the memory cell layer, the second bonding pad structure extends through the bonding layer, the second wiring structure extends through the wiring layer, and the second through via structure extends through the first and second main surfaces of the second substrate.

9. The semiconductor device according to claim 8, wherein second contact plug structure is disposed at the same vertical level as the first contact plug structure, the second bonding pad structure is disposed at the same vertical level as the first bonding pad structure, the second wiring structure is disposed at the same vertical level as the first wiring structure, and the second through via structure is disposed at the same vertical level as the first through via structure.

10. The semiconductor device according to claim 8, wherein a distance between the first main surface of the second substrate and the memory cell layer is less than a distance between the second main surface of the second substrate and the memory cell layer.

11. The semiconductor device according to claim 8, wherein:
the capacitor structure is connected to the first substrate through a first conductive pattern between the first substrate and the capacitor structure,
the hydrogen diffusion path is connected to the first substrate through a second conductive pattern between the first substrate and the hydrogen diffusion path, and
the first conductive pattern is disposed at the same vertical level as the second conductive pattern.

12. The semiconductor device according to claim 8, further comprising a wiring between the first substrate and the capacitor structure,
wherein the hydrogen diffusion path is connected to the capacitor structure through the wiring.

13. The semiconductor device according to claim 8, wherein:
the memory cell layer further includes a first conductive pad between the channel and the capacitor structure,
the first contact plug structure includes a first contact plug, a second conductive pad and a second contact plug, the first contact plug overlapping the bit line structure and the gate structure in the horizontal direction, the second conductive pad overlapping the first conductive pad in the horizontal direction, and the second contact plug overlapping the capacitor structure in the horizontal direction, and
the second contact plug structure includes a third contact plug, a third conductive pad and a fourth contact plug, the third contact plug overlapping the bit line structure and the gate structure in the horizontal direction, the third conductive pad overlapping the first conductive pad in the horizontal direction, and the fourth contact plug overlapping the capacitor structure in the horizontal direction.

14. The semiconductor device according to claim 8, wherein:
the first through via structure includes a first through via extending through the second substrate and a first division pattern at least partially covering a sidewall of the first through via, and
the second through via structure includes a second through via extending through the second substrate and a second division pattern at least partially covering a sidewall of the second through via.

15. A semiconductor device comprising:
a memory cell layer including:
a capacitor structure on a first region of a first substrate, the first substrate including the first region and a second region;
a channel on the capacitor structure;
a gate structure at a side of the channel on the capacitor structure;
a bit line structure on the channel; and
a first contact plug structure overlapping the capacitor structure, the channel and the bit line structure in a horizontal direction parallel to an upper surface of the first substrate;
a second substrate on the memory cell layer;
a transistor layer including a transistor and a first through via structure, the transistor being disposed on an upper surface of the second substrate on the first region of the first substrate, and the first through via structure extending through the second substrate on the first region of the first substrate; and
a hydrogen diffusion path spaced apart from the transistor and including a second contact plug structure and a second through via structure sequentially stacked on an upper surface of the second region of the first substrate in a vertical direction perpendicular to the upper surface of the first substrate,
wherein the second contact plug structure at least partially extends through the memory cell layer, and is disposed at the same vertical level as the first contact plug structure, and
wherein the second through via structure extends through the second substrate, and is disposed at the same vertical level as the first through via structure.

16. The semiconductor device according to claim 15, wherein the first through via structure extends through an upper portion of the memory cell layer, and is connected to the memory cell layer.

17. The semiconductor device according to claim 15, further comprising a bonding layer between the memory cell layer and the second substrate, the bonding layer including a first bonding pad structure on the first region of the first substrate,
wherein:
the first through via structure is connected to the memory cell layer through the first bonding pad structure, and
the hydrogen diffusion path further includes a second bonding pad structure disposed between the second through via structure and the second contact plug structure and extending through the bonding layer.

18. The semiconductor device according to claim 15, wherein:
the memory cell layer further includes a first conductive pad between the channel and the capacitor structure,
the first contact plug structure includes a first contact plug, a second conductive pad and a second contact plug, the first contact plug overlapping the bit line structure and the gate structure in the horizontal direction, the second conductive pad overlapping the first conductive pad in the horizontal direction, and the second contact plug overlapping the capacitor structure in the horizontal direction, and
the second contact plug structure includes a third contact plug, a third conductive pad and a fourth contact plug, the third contact plug overlapping the bit line structure and the gate structure in the horizontal direction, the third conductive pad overlapping the first conductive pad in the horizontal direction, and the fourth contact plug overlapping the capacitor structure in the horizontal direction.

19. The semiconductor device according to claim 15, wherein:
the capacitor structure is connected to the first substrate through a first conductive pattern between the first substrate and the capacitor structure,
the hydrogen diffusion path is connected to the first substrate through a second conductive pattern between the first substrate and the hydrogen diffusion path, and
the first conductive pattern is disposed at the same vertical level as the second conductive pattern.

20. The semiconductor device according to claim 15, further comprising a wiring between the first substrate and the capacitor,
wherein the hydrogen diffusion path is connected to the capacitor structure through the wiring.
